(19) United States
(12) Patent Application Publication
(10) Pub. No.: US 2023/0247845 A1
(43) Pub. Date: Aug. 3, 2023

(54) LEAD ABSORBING MATERIALS FOR THE SEQUESTRATION OF LEAD IN PEROVSKITE SOLAR CELLS

(71) Applicant: The University of North Carolina at Chapel Hill, Chapel Hill, NC (US)

(72) Inventors: Jinsong Huang, Chapel Hill, NC (US); Shangshang Chen, Chapel Hill, NC (US)

(21) Appl. No.: 18/003,520

(22) PCT Filed: Jun. 29, 2021
(86) PCT No.: PCT/US2021/039699

§ 371 Date: Dec. 28, 2022

Related U.S. Application Data
(60) Provisional application No. 63/046,037, filed on Jun. 30, 2020.

(51) Int. Cl. H10K 30/40; H10K 30/82; H10K 85/60; H10K 85/10; H10K 85/50

(52) U.S. Cl. CPC H10K 30/40; H10K 30/821; H10K 85/611; H10K 85/111; H10K 85/50; H10K 2102/101

(57) ABSTRACT

Described herein are solar cells, comprising: an active layer comprising a perovskite composition, wherein the perovskite composition comprises lead; and, a lead-absorbing material. In certain embodiments, the lead-absorbing material is an ion exchange material. The lead absorbing material helps prevent lead leakage in damaged solar cells and solar modules under severe weather conditions.

### CROSS REFERENCE TO RELATED APPLICATIONS

This application claims the benefit and priority to U.S. Provisional Application No. 63/046,037, filed on Jun. 30, 2020, which is hereby incorporated by reference in its entirety.

### FIELD OF THE INVENTION

The presently disclosed subject matter relates generally to perovskite solar cells comprising lead absorbing materials for the prevention of lead leakage in damaged solar cells and solar modules under severe weather conditions.

### BACKGROUND

Power conversion efficiencies (PCEs) have exceeded 25% for single junction perovskite solar cells (PSCs) and 28% for perovskite/silicon tandem solar cells (NREL best research-cell efficiency chart). Large area perovskite modules have successfully been fabricated with scalable coating processes, producing efficiencies comparable to those of silicon modules. The stabilities of perovskite solar cells have also been improved significantly, passing most industrial standard tests (Extance, A. Nature 570, 429-432, (2019); Cheacharoen, R. et al. Sustainable Energy & Fuels 2, 2398-2406, (2018)). All of these developments demonstrate the potential of perovskite photovoltaics as the next-generation low-cost solar technology. Worldwide, perovskite solar cells, including both single junction solar cells, as well as tandem solar cells, are being pursued commercially. Nevertheless, an outstanding concern for the widespread adoption of perovskite photovoltaic technology is the toxicity of lead (Pb) in lead halide perovskite light absorbers (Rong, Y. et al. Science 361, eaat8235, (2018); Rajagopal, A., et al. Adv. Mater. 30, 1800455, (2018)). Although there have been extensive efforts to replace lead in PSCs, lead-free PSCs commonly suffer from either poorer stability, such as the tin-based PSCs, or lower PCEs, such as those exemplified by double-perovskite based solar cells when compared to their lead-based counterparts (Ke, W. & Kanatzidis, M. G. Nat. Commun. 10, 965, (2019); Kamat, P. V., et al. ACS Energy Lett. 2, 904-905, (2017)). As such, lead helps promote perovskite PSCs with both high efficiencies and good operational stability (Yang, S. et al. Science 365, 473-478, (2019); Wang, L. et al. Science 363, 265-270, (2019); Wang, Y. et al. Science 365, 687-691, (2019); Tan, H. et al. Science 355, 722-726, (2017)). While several methods have been investigated with the aim of trapping lead in perovskite solar cells, such efforts have faced low success in situations where the solar cells are damaged in extreme weather conditions, such as hail or snowstorms. Once damaged, toxic lead can leak out of the perovskite layers during rainfall, and then enter and contaminate soil and underground water. As such, what is needed in the art are effective, low-cost methods that can be easily integrated into the production line of perovskite solar cells for the prevention of lead leakage. The subject matter described herein addresses this unmet need.

### BRIEF SUMMARY

In one aspect, the presently disclosed subject matter is directed to a solar cell, comprising: an active layer comprising a perovskite composition, wherein the perovskite composition comprises lead; and, a lead absorbing material.

In another aspect, the presently disclosed subject matter is directed to a solar module comprising a plurality of solar cells, wherein the solar cells comprise a lead absorbing material and a perovskite composition, wherein the perovskite composition comprises lead.

These and other aspects are described herein.

### BRIEF DESCRIPTION OF THE DRAWINGS

FIG. 1A shows a schematic of how cation exchange resins prevent lead leakage due to the strong ionic interaction between Pb²⁺ in decomposed perovskites and sulfonic acid groups.

FIG. 1B shows the concentration change of lead-containing water after flowing on a 15-cm-long glass covered by resin layers with different thicknesses tested at 20° C.

FIG. 1C shows a SEM image of a top-view of a MAPbI₃ device with a cation exchange resin back coating.

FIG. 1D shows a SEM image of a cross-sectional view of a MAPbI₃ device with a cation exchange resin back coating.

FIG. 2A shows nitrogen adsorption-desorption isotherms of cation exchange resins investigated herein.

FIG. 2B shows a BET pore size distributions of cation exchange resins investigated herein.

FIG. 3 shows a plot indicating lead concentration evolution over time after mixing 10 mg cation exchange resins with 50 mL 100 ppm lead aqueous solution.

FIG. 4 shows a SEM image of a cross-sectional view of a glass substrate with a front resin coating layer.

FIG. 5 shows a photograph of a water droplet on resin-coated glass.

FIG. 6 shows J-V characteristics of a MAPbI₃ PSC without and with a cation exchange resin back coating.

FIG. 7A shows pictures of the steps involved in the typical preparation processes of damaged perovskite solar mini-modules for lead leakage tests. The cells in the mini-module can connect in series or in parallel. (1) Image of a large MAPbI₃ mini-module with a perovskite-covered area of 102.0 cm²; (2) The large module was cut into two identical small modules; (3) Back of two small modules: the right one was coated with cation exchange resins; (4) Front and (5) back of encapsulated small modules at the edge with epoxy resin; (6) Mechanically damaged small modules.

FIG. 7B shows water-soaking test results of the damaged small modules without and with a resin coating layer (top four responses: control modules without resin layer encapsulated by glass slide; bottom four responses: the modules with back resin layer encapsulated by glass slide;

FIG. 7C shows water-dripping test results of the damaged small modules without and with a resin coating layer (left-most bar: control modules without resin layer encapsulated by glass slide; center bar: the modules with back resin layer encapsulated by glass slide; right-most bar: the small modules with both front and back resin layers encapsulated by PP board).

FIG. 8 shows a photograph of the setup for water-dripping tests.

FIG. 9 shows a photograph of an outdoor lead leakage test on two damaged solar modules with (left) and without (right) resin coating layers on a rainy day.

FIG. 10A shows a plot of the transmittance spectrum of the ITO substrate without and with a front resin coating layer.

FIG. 10B shows a plot of an EQE spectrum of the MAPbI₃ solar cells based on the ITO glass substrate without and with a front resin coating layer.

FIG. 11 shows photographs of (a) a PP board, (b) a perovskite solar module with the back side encapsulated by the PP board, and the front (c) and back (d) of a PP-encapsulated perovskite solar module after hail impact.

FIG. 12A shows a device structure of carbon-based PSCs.

FIG. 12B shows I-V curves of glass/carbon:resin film/Ag lateral devices.

FIG. 12C shows J-V curves of PSCs based on carbon electrodes with different carbon paste/resin weight ratios.

FIG. 12D shows a SEM image of a cross-sectional view of neat carbon paste-based PSCs.

FIG. 12E shows a SEM image of a cross-sectional view of carbon PSCs with a carbon/resin (5:1) electrode. Scale bar is 3 μm.

FIG. 12F shows an EDS image of carbon PSCs with a carbon/resin (5:1) electrode. Scale bar is 3 μm.

FIG. 13 shows a plot of J-V curves of the hole-conductor-free PSCs with different carbon paste/resin ratios.

FIG. 14A shows the carbon perovskite solar panel with a typical size of 198 cm×99 cm for lead leakage simulation.

FIG. 14B shows the mapping of lead concentration on the damaged solar panel at a rain flow speed of zero.

FIG. 14C shows a plot of the concentration of the rain reaching the bottom of solar panel versus initial rainwater flowing speed.

FIG. 15A shows the structure of sulfonic acid cation exchange resins (SACERs).

FIG. 15B shows a device structure having SACERS suspended in isopropyl alcohol and then bladed coated on the top of poly(triaryl amine) (PTAA) covered indium tin oxide (ITO) glass substrate.

FIG. 15C shows a SEM image of a cross-sectional view of SACERS embedded in a perovskite solar cell.

FIG. 16A shows a plot of J-V curves of solar cells containing MAPbI₃ with and without SACERs in the perovskite layer.

FIG. 16B shows a plot of the stabilized power output of solar cells containing MAPbI₃ with and without SACERs in the perovskite layer.

FIG. 16C shows a plot of transient photovoltage decay curves of solar cells containing MAPbI₃ with and without SACERs in the perovskite layer.

FIG. 16D shows a plot of the trap density of states of solar cells containing MAPbI₃ with and without SACERs in the perovskite layer.

FIG. 16E shows a picture of MAPbI₃ films under 1-sun light soaking without (left) and with (right) SACERs.

FIG. 17A shows a SEM image of the top view of MAPbI₃ films on glass/ITO/PTAA without (left) and with (right) the incorporation of SACERs.

FIG. 17B shows XRD spectra of MAPbI₃ films on glass/ITO/PTAA without and with the incorporation of SACERs.

FIG. 17C shows a plot of the transmittance of ITO glass substrates without and with the incorporation of SACERs.

FIG. 18A shows the architectures of encapsulated perovskite mini-modules for a lead leakage test, where the resin is embedded within the perovskite layer.

FIG. 18B shows the setup for the water-dripping lead leakage test for encapsulated perovskite mini-modules having the resin embedded in the perovskite layer.

FIG. 18C shows a bar graph with the results of the water-dripping lead leakage test for perovskite solar cells, wherein the resin is embedded within the perovskite layer.

FIG. 19 shows chemical structures of non-limiting lead-adsorbing materials for forming electrostatic forces to lead cations.

FIG. 20 shows chemical structure of non-limiting molecules for forming complexes with lead cations.

FIG. 21 shows several non-limiting examples of device structures of perovskite solar devices integrated with lead adsorbent material. TCO is transparent conductive oxide; HTL is hole transporting layer; ETL is electron transporting layer.

FIG. 22 shows additional non-limiting examples of device structures of perovskite solar devices integrated with lead adsorbent material.

FIG. 23 shows non-limiting examples of perovskite tandem solar cells with lead adsorbent material distributions. Perovskite/silicon tandem solar cell architectures are shown. In these devices, the recombination layer is the intermediate layer that allows the recombination of holes coming from one sub-cell with electrons coming from the other.

FIG. 24 shows non-limiting examples of perovskite/perovskite tandem solar cells with lead adsorbent material distributions.

FIG. 25 shows additional non-limiting examples of perovskite/perovskite tandem solar cells with lead adsorbent material distributions.

FIG. 26 shows non-limiting examples of perovskite/thin film tandem solar cells with lead adsorbent material distributions. The thin film sub-cell materials include but are not limited to organic, cadmium telluride (CdTe), copper indium gallium selenide, and gallium arsenide solar cells.

FIG. 27 shows additional non-limiting examples of perovskite/thin film tandem solar cells with lead adsorbent material distributions.

### DETAILED DESCRIPTION

The subject matter described herein relates to new materials and methods for preventing lead leakage in lead-containing perovskite photovoltaics. The methods are based on lead-adsorbing coating layers that can effectively minimize lead leakage in damaged perovskite solar modules. The methods offer significant advantages compared to those in the art, such as low-cost and abundant materials. Instead of exploring lead-free compositions or reducing the amount of lead in perovskite solar devices, the subject matter described herein offers a new pathway to reduce the impact of toxic lead by preventing lead leakage in damaged perovskite solar devices, thereby helping to tackle the challenges related to the commercialization of perovskite-based technologies.

One strategy used to minimize the impact of toxic lead in the environment as a result of lead leakage from perovskite solar cells involves the application of an encapsulation material in damaged or broken calls. Jiang et al., for example, developed a self-healing polymer-based encapsulation method for suppressing lead leakage (Jiang, Y. et al. Nat. Energy 4, 585-593, (2019). The self-healing effect of the polymer encapsulant at higher temperatures can prevent water from penetrating into the damaged perovskite solar modules. However, methods that can effectively prevent lead leakage regardless of operation temperature would be more advantageous. Additionally, encapsulation techniques cannot completely prevent Pb leakage, as Pb can still emerge from the solar panels with rainwater under extreme weather conditions.

The abundant, low-cost, and chemically robust lead absorbing materials described herein can prevent lead leakage in damaged perovskite solar modules under severe weather conditions. The lead-adsorbing materials are prepared from cation exchange resins, which exhibit both strong bonding and excellent selectivity to Pb²⁺ cations in water. The cation exchange resins are economical, chemically tough, water-insoluble, and can be easily integrated into perovskite solar modules. As demonstrated by water soaking and dripping tests, the cation exchange resins coated on surfaces of metal electrode-based solar mini-modules can effectively reduce lead leakage by ˜90%, independent of test temperature, compared to mini-modules without the resin layers. Further demonstrated is the successful integration of lead-adsorbing resins into carbon electrodes of perovskite solar cells without detrimental effects on device efficiencies. Integration of the cation exchange resins in carbon electrodes and glass enables the lead leakage in carbon-based solar mini-modules to be reduced from 891 ppb to 14.3 ppb, which is within the U.S. Federal 40 CFR 141 regulation's safe level of drinking water. All of these features make the cation exchange resins described herein an ideal candidate to prevent lead leakage in damaged perovskite solar modules.

Ion exchange resins are used in a number of different fields, from water softening, to wastewater treatment, and from chromatography, to biomolecular separations and catalysis (Alexandratos, S. D. Ind. Eng. Chem. Res. 48, 388-398, (2009). One of the greatest demands for ion exchange resins comes from wastewater treatment as a result of the effectiveness of the cation exchanger in removing heavy metals in industrial wastewater. This efficacy originates from the strong bonding between strong acid groups of resins (typically sulfonic acid groups) and metal cations. The affinity of sulfonic acid resins for cations varies with ionic size and charge of the cation. Without wishing to be bound by theory, for the strong acidic cation exchanger, the affinity is greater for large ions with high valency, and thus the affinity series can be ordered as follows: Al³⁺>Pb²⁺>Ca²⁺>Ni²⁺>Cd²⁺>Cu²⁺>Zn²⁺>Mg²⁺>Ag⁺>Na⁺¹⁴. As such, the cation exchanger exhibits strong ionic bonding to Pb²⁺ in aquatic environments. Additionally, cation exchange resins have been widely used in wastewater treatment, which has resulted in the material's relative abundance and low cost (<0.01 USD g⁻¹). Furthermore, cation exchange resins are typically cross-linked, and thus mechanically and chemically robust to survive in environments with various pH values. In addition, they have a large surface area to adsorb heavy metal ions due to their microscopic porous structure (Alexandratos, S. D. Ind. Eng. Chem. Res. 48, 388-398, (2009); Da̧browski, A. et al. Chemosphere 56, 91-106, (2004). As such, the cation exchange resins described herein are ideal for alleviating lead leakage in perovskite-based devices.

The presently disclosed subject matter will now be described more fully hereinafter. However, many modifications and other embodiments of the presently disclosed subject matter set forth herein will come to mind to one skilled in the art to which the presently disclosed subject matter pertains having the benefit of the teachings presented in the foregoing descriptions. Therefore, it is to be understood that the presently disclosed subject matter is not to be limited to the specific embodiments disclosed and that modifications and other embodiments are intended to be included within the scope of the appended claims. In other words, the subject matter described herein covers all alternatives, modifications, and equivalents. Unless otherwise defined, all technical and scientific terms used herein have the same meaning as commonly understood by one of ordinary skill in this field. All publications, patent applications, patents, and other references mentioned herein are incorporated by reference in their entirety. In the event that one or more of the incorporated literatures, patents, and similar materials differs from or contradicts this application, including but not limited to defined terms, term usage, described techniques, or the like, this application controls.

### I. Definitions

As used herein, “and/or” refers to and encompasses any and all possible combinations of one or more of the associated listed items, as well as the lack of combinations when interpreted in the alternative (“or”).

As used herein, the term “about,” when referring to a measurable value such as an amount of a compound or agent of the current subject matter, dose, time, temperature, and the like, is meant to encompass variations of ±20%, ±10%, ±5%, ±1%, ±0.5%, or even ±0.10% of the specified amount.

The terms “approximately,” “about,” “essentially,” and “substantially” as used herein represent an amount close to the stated amount that still performs a desired function or achieves a desired result. For example, in some embodiments, as the context may dictate, the terms “approximately”, “about”, and “substantially” may refer to an amount that is within less than or equal to 10% of the stated amount. The term “generally” as used herein represents a value, amount, or characteristic that predominantly includes or tends toward a particular value, amount, or characteristic.

As used herein, conditional language used herein, such as, among others, “can,” “could,” “might,” “may,” “e.g.,” and the like, unless specifically stated otherwise or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As used herein, “PSC” refers to perovskite solar cell.

As used herein, “active layer” refers to a photoactive layer in a device, such as a solar cell, and/or it may include a photoactive material. Furthermore, it should be noted that the use of the term “active layer” is in no way meant to restrict or otherwise define, explicitly or implicitly, the properties of any other layer in the device.

As used herein, when an element such as a layer, a film, a region, or a substrate is referred to as being “on” another element, it can be directly on the other element, or an intervening element may also be present. In contrast, when an element is referred to as being “directly on” another element, there are no intervening elements present.

### II. Polycrystalline Compositions

In one aspect, the subject matter described herein is directed to an active layer comprising a perovskite composition, wherein the perovskite composition comprises lead.

In certain embodiments, the perovskite composition is a composition of Formula (I)

ABX₃ (I)

wherein A is a cation selected from the group consisting of methylammonium (MA), tetramethylammonium (TMA), formamidinium (FA), cesium (Cs), rubidium (Rb), potassium (K), sodium (Na), calcium (Ca), butylammonium (BAH), phenethylammonium (PEA), phenylammonium (PHA), guanidinium (Gu), ammonium, and a combination thereof;

B is at least one metal cation comprising lead; and

X is selected from the group consisting of chloride, bromide, fluoride, iodide, thiocyanate, and a combination thereof.

In certain embodiments, A may comprise an ammonium, an organic cation of the general formula [NR₄]⁺ where the R groups can be the same or different groups. Suitable R groups include, but are not limited to: methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OC_{X}H_{y}, where x=0-20, y=1-42. In certain embodiments, A is methylammonium, (CH₃NH₃+). In certain embodiments, A is methylammonium. In certain embodiments, A is tetramethylammonium, ((CH₃)₄N+). In certain embodiments, A is butylammonium, which may be represented by (CH₃(CH₂)₃NH₃⁺) for n-butylammonium, by ((CH₃)₃CNH₃⁺) for t-butylammonium, or by (CH₃)₂CHCH₂NH₃⁺) for iso-butylammonium. In certain embodiments, A is phenethylammonium, which may be represented by C₆H₅(CH₂)₂NH₃ or by C₆H₅CH(CH₃)NH₃⁺. In certain embodiments, A comprises phenylammonium, C₆H₅NH₃⁺.

In certain embodiments, A may comprise a formamidinium, an organic cation of the general formula [R₂NCHNR₂]⁺ where the R groups can be the same or different groups. Suitable R groups include, but are not limited to: hydrogen, methyl, ethyl, propyl, butyl, pentyl or an isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., imidazole, benzimidazole, dihydropyrimidine, (azolidinylidenemethyl)pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. As used herein, when A is a formamidinium ion, it refers to (H₂N═CH—NH₂+).

In certain embodiments, A may comprise a guanidinium, an organic cation of the general formula [(R₂N)₂C═NR₂]⁺ where the R groups can be the same or different groups. Suitable R groups include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a]imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A is a guanidinium ion of the type (H₂N═C—(NH₂)₂⁺).

In certain embodiments, A may comprise an alkali metal cation, such as Li⁺, Na⁺, K⁺, Rb⁺, or Cs⁺.

In certain embodiments, the perovskite crystal structure composition may be doped (e.g., by partial substitution of the cation A and/or the metal B) with a doping element, which may be, for example, an alkali metal (e.g., Li⁺, Na⁺, K⁺, Rb⁺, or Cs⁺), an alkaline earth metal (e.g., Mg²⁺, Ca²⁺, Sr²⁺, Ba²⁺) or other divalent metal, such as provided below for B, but different from B (e.g., Sn²⁺, Pb²⁺, Zn²⁺, Cd²⁺, Ge²⁺, Ni²⁺, Pt²⁺, Pd²⁺, Hg²⁺, Si²⁺, Ti²⁺), or a Group 15 element, such as Sb, Bi, As, or P, or other metals, such as silver, copper, gallium, indium, thallium, molybdenum, or gold, typically in an amount of up to or less than about 1, 5, 10, 20, 25, 30, 35, 40, 45, 50, 55, 60, 65, 70, 75, 80, 85, 90, 95, 99, or 100 mol % of A or B. A may comprise a mixture of cations. B may comprise a mixture of cations.

In embodiments, B is a divalent metal. The variable B comprises at least lead. B can be, for example, one or more elements from Group 14 of the Periodic Table comprising lead and tin, or germanium, or one or more transition metal elements from Groups 3-12 of the Periodic Table (e.g., titanium, vanadium, chromium, manganese, iron, cobalt, nickel, copper, zinc, palladium, platinum, and cadmium), and/or one or more alkaline earth elements (e.g., magnesium, calcium, strontium, and barium). In certain embodiments, B is selected from the group consisting of lead and at least one of tin, cadmium, germanium, zinc, nickel, platinum, palladium, mercury, titanium, silicon. In certain embodiments, B is lead.

In certain embodiments, the variable X is independently selected from one or a combination of chloride, bromide, fluoride, iodide, and thiocyanate. In certain embodiments, X is selected from the group consisting of SCN⁻, BF₄⁻, F⁻, Cl⁻, Br⁻, I⁻, and a combination thereof. In certain embodiments, X is a halide selected from the group consisting of F⁻, Cl⁻, Br⁻, I⁻, and a combination thereof.

In certain embodiments, the perovskite composition of Formula (I) is selected from the group consisting of MAPbI₃, MAPbBr₃, and MAPbCl₃. In certain embodiments, the perovskite composition is MAPbI₃.

In certain embodiments, the perovskite composition is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), and formamidinium lead iodide (CHNH₂NH₂PbI₃).

In certain embodiments of the perovskite composition of Formula (I), A is selected from the group consisting of Cs, FA, MA, Rb, and a combination thereof, B is lead; and X is selected from the group consisting of iodide, bromide, and a combination thereof. In certain embodiments, the perovskite composition is RbₓCs_{y}FA_{1-x-y-z}MA_{z}PbI_{3-f}Br_{f}, wherein ((x+y+z)<1; f≤3). In certain embodiments, the perovskite composition is RbₓCs_{y}FA_{1-x-y-z}MA_{z}PbI_{3-f}Br_{f}, wherein x is 0.01-0.15, y is 0.01-0.15, z is 0.01-0.15, and f is 0.05-0.50. In certain embodiments, the perovskite composition is RbₓCs_{y}FA_{1-x-y-z}MA_{z}PbI_{3-f}Br_{f}, wherein x is 0.01-0.50, y is 0.01-0.25, z is 0.01-0.35, and f is 0.05-2.5. In certain embodiments, the perovskite composition is RbₓCs_{y}FA_{1-x-y-z}MA_{z}PbI_{3-f}Br_{f}, wherein x is 0.05, y is 0.05, z is 0.05, and f is 0.15. In certain embodiments, the perovskite composition is Rb_{0.05}Cs_{0.05}FA_{0.85}MA_{0.05}PbI_{2.85}Br_{0.15}.

In embodiments, the perovskite composition comprises a polycrystalline film having an average grain size of about 10 nm to about 1 mm. In certain embodiments, the polycrystalline perovskite films have an average grain size of about 100 nm to about 300 nm. In certain embodiments, the crystalline perovskite films have an average grain size of about, at least, or above 0.01 μm, 10 μm, 20 μm, 30 μm, 40 μm, 50 μm, 60 μm, 70 μm, 80 μm, 90 μm, 100 μm, 120 μm, 150 μm, 180 μm, 200 μm, 220 μm, 250 μm, 280 μm, 300 μm, 350 μm, 400 μm, 450 μm, 500 μm, 550 μm, 600 μm, 650 μm, 700 μm, 800 μm, 850 μm, 900 μm, 1000 μm, or an average grain size within a range bounded by any two of the foregoing exemplary values.

In embodiments, the perovskite composition comprises a polycrystalline film having a film thickness in the range of about 10 nm to about 1 cm. In certain embodiments, the polycrystalline perovskite films have a thickness of about 400 nm to about 600 nm. In certain embodiments, the polycrystalline perovskite films have a thickness of about 500 nm. In certain embodiments, the polycrystalline perovskite films have a thickness in the range of about 80 nm to about 300 nm. In certain embodiments, the polycrystalline perovskite films have a thickness in the range of about 0.1 mm to about 50 mm. In certain embodiments, the polycrystalline perovskite films have a thickness in the range of about 100 nm to about 1000 nm. In certain embodiments, the perovskite films have a film thickness of about, at least, above, up to, or less than, for example, 200 nm, 300 nm, 400 nm, 500 nm, 600 nm, 700 nm, 800 nm, 900 nm, 1000 nm (1 μm), 2 μm, 3 μm, 4 μm, 5 μm, 6 μm, 7 μm, 8 μm, 9 μm, or 10 μm.

In embodiments, the perovskite composition comprises a polycrystalline film that is smooth. In certain embodiments, the polycrystalline perovskite films have a root mean square surface roughness of about 23.0 nm, 23.1 nm, 23.2 nm, 23.3 nm, 23.4 nm, 23.5 nm, 23.6 nm, 23.7 nm, 23.8 nm, 23.9 nm, 24.0 nm, 24.1 nm, 24.2 nm, 24.3 nm, 24.4 nm, 24.5 nm, 24.6 nm, 24.7 nm, 24.8 nm, 24.9 nm, 25.0 nm, 25.1 nm, 25.2 nm, 25.3 nm, 25.4 nm, 25.6 nm, 25.7 nm, 25.8 nm, 25.9 nm, or 26.0 nm as measured by Atomic Force Microscopy (AFM) scanning.

### III. Lead Absorbing Materials

In embodiments, the subject matter disclosed herein is directed to solar cells comprising a lead absorbing material. As used herein, “lead absorbing material” refers to a material that has strong bonding interactions with lead (Pb²⁺). Additionally, as used herein, lead absorbing materials, which exhibit strong bonding interactions with lead (Pb²⁺), also include lead adsorbing materials.

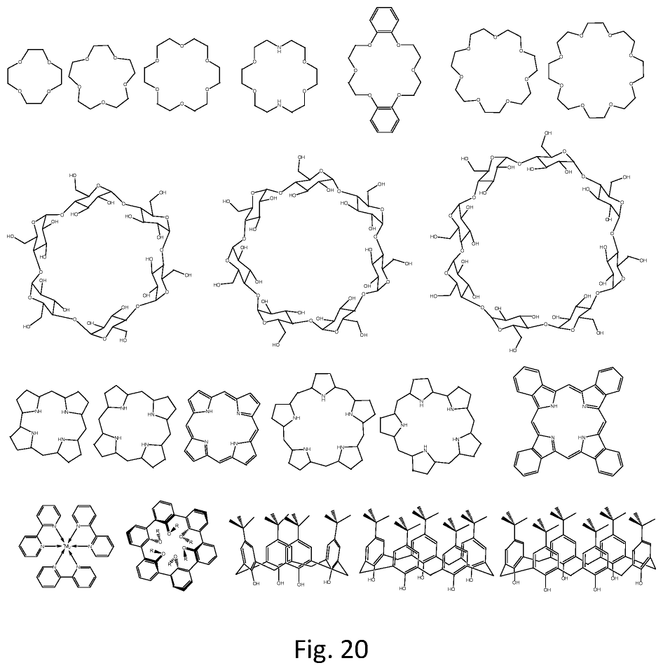

In certain embodiments, the lead absorbing molecule is a neutral molecule that can form a complex with lead. Non-limiting examples of neutral molecule that can form coordination complexes with lead are provided in FIG. 20. In certain embodiments, the neutral molecule is selected from the group consisting of crown ether, cyclodextrin, porphyrin, calixarene, calixcarbazole, pillararene, and cucurbituril.

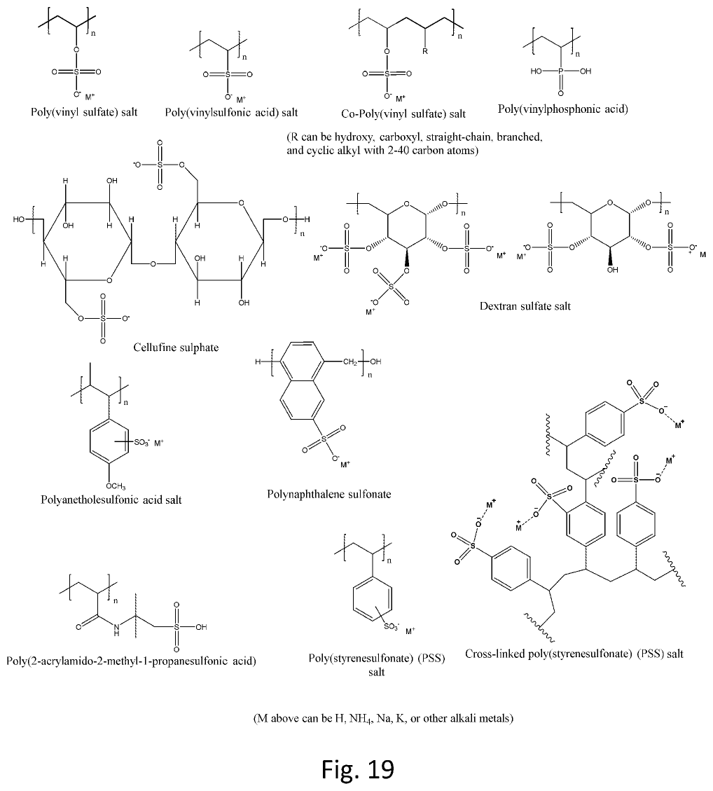

In certain embodiments, the lead absorbing material is an ion exchange material. Ion exchange resins include weak and strong acid cation exchange resins and weak and strong anion exchange resins of either a gel or macroporous type. In embodiments, the lead absorbing material is an ion exchange resin comprising a negatively-charged functional group selected from the group consisting of SO₃²⁻ (sulfite), SO₃²⁻ (sulfonate), SO₄²⁻ (sulfate), C₆H₅O₇⁻³ (citrate), C₄H₄O₆²⁻ (tartrate), PO₄³⁻ (phosphate), CO₃²⁻ (carbonate), AsO₄³⁻ (arsenate), ClO₄⁻ (perchlorate), SCN⁻ (thiocyanate), S₂O₃²⁻ (thiosulfate), WO₄²⁻ (tungstate), MoO₄²⁻ (molybdate), CrO₄²⁻ (chromate), C₂O₄²⁻ (oxalate), HSO₄⁻ (hydrogen sulfate), HPO₄²⁻ (hydrogenphosphate), NO₃⁻ (nitrate), NO₂⁻ (nitrite), CN⁻ (cyanide), Cl⁻ (chloride), HCO₃⁻ (bicarbonate), H₂PO₄⁻ (dihydrogenphosphate), CH₃COO⁻ (acetate), IO₃⁻ (iodate), HCOO⁻ (formate), BrO₃⁻ (bromate), ClO₃⁻ (chlorate), F⁻ (fluoride), and OH⁻ (hydroxide). In certain embodiments, the ion exchange material comprises a sulfonate functional group. Non-limiting examples of these ion exchange materials are set forth in FIG. 19.

Negatively-charged ion exchange materials are generally known in the art as cationic exchange resins. Non-limiting examples of cationic exchange resins include monovinylidene aromatic crosslinked polymer, or (meth) acrylic acid ester-based crosslinked polymer. Concrete non-limiting examples include resins derived from monovinylidene aromatic monomers such as styrene or vinyl toluene and copolymerizable crosslinking agents, as well as resins derived from acrylic monomers such as acrylic acid or methacrylic acid and copolymerizable crosslinking agents. Non-limiting examples of crosslinking agents include di- or polyvinylidene aromatic agents such as divinyl benzene and divinyl toluene, or ethylene glycol dimethacrylate. Strongly acidic cation exchange resins (SACERs) have sulfonic-acid groups or phosphonic-acid groups as the functional group, while mildly acidic cationic exchange resins have carboxylic-acid groups, phosphinic-acid groups, phenoxide groups, arensite groups and the like.

In certain embodiments, the ion exchange material is polystyrene sulphonate. In certain embodiments, the ion exchange material is crosslinked. In certain embodiments, the polystyrene sulphonate is crosslinked polystyrene sulphonate. In certain embodiments, the crosslinked polystyrene sulphonate is selected from the group consisting of crosslinked calcium polystyrene sulphonate, crosslinked hydrogen polystyrene sulphonate, crosslinked sodium polystyrene sulphonate, and crosslinked potassium polystyrene sulphonate. In certain embodiments, the polystyrene sulphonate is crosslinked sodium polystyrene sulphonate. In certain embodiments, the polystyrene sulphonate is crosslinked magnesium styrene sulfonate, crosslinked lithium styrene sulfonate, crosslinked aluminum styrene sulfonate, crosslinked ferrous styrene sulfonate, crosslinked ferric styrene sulfonate, or crosslinked ammonium styrene sulfonate.

The styrene sulfonate metal may be produced, for example, as set forth in chapter 4 of Functional Monomers, vol. 1, Yocum et al. ed. (Marcel Dekker, Inc., 1973), by sulfonating ethylbenzene with chlorosulfuric acid (or with sulfuric acid followed by chlorination with PCl₅) to produce p-ethylbenzenesulfonyl chloride, which is then purified by fractional distillation, brominated, and subsequently debrominated with the hydroxide of the desired metal. When NaOH is used in the process, sodium styrene sulfonate is produced.

Non-limiting examples of resins include AMBERLITE IRC 747, AMBERSEP 400 SO4, AMBERSEP 4400 HCO3, AMBERSEP 748 UPS, AMBERSEP 920 UXL Cl, AMBERSEP 920U C1, AMBERSEP 920UHCSO4, AMBERSEP GT74, DOWEX™ 21K 16-20, DOWEX 21K XLT, DOWEX Mac-3, DOWEX RPU, XUS-43578, XUS-43600, XUS-43604, XUS-43605, and XZ-91419, all available from The Dow Chemical Company, Midland, Mich. In certain embodiments, the exchange resin is AMBERLITE IR120, AMBERJET1500, AMBERLYST 15 (macro reticular polystyrene based ion exchange resin with strongly acidic sulfonic group), or AMBERSEP 200.

In certain embodiments, the surface area and pore diameter of the resin powder described herein are 45.9 m² g⁻¹ and 22.6 nm, as determined by a Brunauer-Emmett-Teller (BET) surface area and pore size analyzer. In certain embodiments, the surface area of the resin powder described herein is about 40 m² g⁻¹, 41 m² g⁻¹, 42 m² g⁻¹, 43 m² g⁻¹, 44 m² g⁻¹, 45 m² g⁻¹, 46 m² g⁻¹, 47 m² g⁻¹, 48 m² g⁻¹, 49 m² g⁻¹, or 50 m² g⁻¹. In certain embodiments, the pore diameter of the resin powder described herein is about 13 nm, 14 nm, 15 nm, 16 nm, 17 nm, 18 nm, 19 nm, 20 nm, 21 nm, 22 nm, 23 nm, 24 nm, 25 nm, 26 nm, or 27 nm.

In embodiments, the lead absorbing material does not comprise P,P′-di(2-ethylhexyl)methanediphosphonic acid; enediaminetetrakis(methylenephosphonic acid); or tetraethylene glycol-substituted 2,1,3-benzothiadiazole. As used herein, tetraethylene glycol-substituted 2,1,3-benzothiadiazole refers to tetraethylene glycol-substituted 2,1,3-benzothiadiazole or any molecule or polymer comprising a tetraethylene glycol-substituted 2,1,3-benzothiadiazole moiety. As used herein, P,P′-di(2-ethylhexyl)methanediphosphonic acid refers to P,P′-di(2-ethylhexyl)methanediphosphonic acid or any molecule or polymer comprising a P,P′-di(2-ethylhexyl)methanediphosphonic acid moiety. As used herein, enediaminetetrakis(methylenephosphonic acid) refers to enediaminetetrakis(methylenephosphonic acid) or any molecule or polymer comprising a enediaminetetrakis(methylenephosphonic acid) moiety.

### IV. Solar Cells and Solar Modules

The subject matter described herein is directed to a solar cell, comprising a lead-adsorbing material and a perovskite composition, wherein said perovskite composition comprises lead. In certain embodiments, the solar cell is a single junction solar cell. In certain embodiments, the solar cell is a tandem solar cell.

In embodiments, the perovskite solar cell comprises a transparent conductive oxide layer and a metal electrode; wherein: the perovskite composition is disposed on the transparent conductive oxide layer and the metal electrode is disposed on the perovskite composition.

An element can include more than one sublayer, for example, the ETL or HTL can include sublayers known in the art and containing different materials, such as a buffer sublayer or coating sublayer, that are described herein as part of the same element. Each element, however, is a distinct section having a discrete function from other elements in the perovskite solar cell or solar module. For example, in certain embodiments, the ETL can comprise PCBM/BCP, PCBM/TiO₂, PCBM/LiF, C60/BCP, PCBM/PFN, or PCBM/ZnO. In certain other embodiments, the ETL can comprise a material selected from the group consisting of C60, BCP, TiO₂, SnO₂, PCBM, ICBA, ICMA, ZnO, ZrAcac, LiF, TPBI, PFN; and, a buffer sublayer disposed on the ETL material selected from the group consisting of PDI, PDINO, PFN, PFN—Br, SnO₂, ZnO, ZrAcac, TiO₂, BCP, LiF, PPDIN6, and TPBi. In certain embodiments, the HTL can comprise one or more materials selected from the group consisting of PTAA, Poly-TPD, Spiro-OMeTAD, PEDOT:PSS, NiO, MoO3, V2O5, and EH44. In certain other embodiments, the perovskite solar cells or perovskite tandem cells may comprise a coating sublayer, such as an antireflective coating material. Nonlimiting examples of antireflective coating materials include MgF₂ and LiF.

In certain embodiments, the perovskite solar cell comprises a first transparent conductive oxide layer and a second transparent conductive oxide layer. In certain embodiments, the perovskite composition is disposed on the first transparent conductive oxide layer and the second transparent conductive oxide layer is disposed on the perovskite composition. In certain embodiments of the perovskite solar cell comprising a first transparent conductive oxide layer and a second transparent conductive oxide layer, wherein the perovskite composition is disposed on the first transparent conductive oxide layer and the second transparent conductive oxide layer is disposed on the perovskite composition, the solar cell further comprises an electron transport layer and a hole transport layer, wherein the hole transport layer is disposed on the first transparent conductive oxide layer, the perovskite composition is disposed on the hole transport layer, the electron transport layer is disposed on the perovskite composition, and the second transparent conductive oxide layer is disposed on the electron transport layer. In certain embodiments, the solar cell further comprises a glass layer disposed on the second transparent conductive oxide layer. In certain other embodiments, the solar cell further comprises a glass layer, wherein the first transparent conductive oxide layer is disposed on the glass layer. In certain embodiments, the lead absorbing material is in a lead absorbing material layer, wherein the lead absorbing material layer is disposed on the second transparent conductive oxide layer. In certain embodiments, the lead absorbing material is in a lead absorbing material layer, wherein the first transparent conductive oxide layer is disposed on the lead absorbing material layer.

In certain embodiments, the solar cell further comprises: a first transport layer and a second transport layer; wherein: the first transport layer is disposed on the transparent conductive oxide layer; the perovskite composition is disposed on the first transport layer; the second transport layer is disposed on the perovskite composition; and the metal electrode is disposed on the second transport layer.

The transparent conductive oxide layer and the metal electrode comprise the anode and cathode (or vice versa) in the solar cell. In certain embodiments, a first transparent conductive oxide layer and a second transparent conductive oxide layer comprise the anode and cathode (or vice versa) in the solar cell. In certain embodiments, the cathode and anode each comprise at least one of lithium, sodium, potassium, rubidium, cesium, francium, beryllium, magnesium, calcium, strontium, barium, radium, boron, aluminum, gallium, indium, thallium, tin, lead, flerovium, bismuth, antimony, tellurium, polonium, scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, copernicium, samarium, neodymium, ytterbium, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, carbon nanowire, carbon nanosheet, carbon nanorod, carbon nanotube, graphite, indium tin oxide (ITO), fluorine-doped tin oxide (FTO), aluminum doped zinc oxide (AZO), antimony-tin mixed oxide (ATO), network of metal/alloy nanowire, or a combination of two or more of the above materials. In certain embodiments, the transparent conductive oxide layer is selected from the group consisting of ITO, FTO, ZITO, and AZO. In certain embodiments, the metal electrode is selected from the group consisting of Al, Au, Cu, Cr, Ca, Mg, Bi, Ag, and Ti.

The transport layers in the solar cell are each a hole transport layer or an electron transport layer.

In certain embodiments, the charge transport layer between the perovskite composition and the cathode (hole transport layer) comprises at least one of poly(3,4-ethylene dioxithiophene) (PEDOT) doped with poly(styrene sulfon icacid) (PSS), Spiro-OMeTAD, pm-spiro-OMeTAD, po-spiro-OMeTAD, dopants in spiro-OMeTAD, 4,4′-biskptrichlorosilylpropylphenyl)pheny laminoThiphenyl (TPD-Si2), poly(3-hexyl-2,5-thienylene vinylene) (P3HTV), C60, carbon, carbon nanotube, graphene quantum dot, graphene oxide, copper phthalocyanine (CuPc), Polythiophene, poly(3,4-(1hydroxymethyl)ethylenedioxythiophene (PHMEDOT), n-dodecylbenzenesulfonic acid/hydrochloric acid doped poly(aniline) nanotubes (a-PANIN)s, poly(styrene sulfonic acid)-graft-poly(aniline) (PSSA-g-PANI), poly(9,9-dioctylfluorene)-co-N-(4-(1-methylpropyl)phenyl) diphenylamine (PFT), 4,4′-bis(p-trichlorosilylpropylphenyl) phenylaminobiphenyl (TSPP), 5,5′-bis(p-trichlorosilylpropylphenyl) phenylamino-2,20 bithiophene (TSPT), N-propyltriethoxysilane, 3,3,3-trifluo ropropyltrichlorosilane or 3-aminopropyltriethoxysilane, Poly(bis(4-phenyl)(2,4,6-trimethylphenyl)amine) (PTAA), (Poly[[(2,4-dimethylphenyl)imino]-1,4-phenylene(9,9-dioctyl-9H-fluorene-2,7-diyl)-1,4phenylene], (PF8-TAA)), (Poly [[(2,4-dimethylphenyl)imino]-1,4-phenylene (6,12-dihydro-6,6,12,12tetraoctylindeno[1,2-b]fluorene-2,8-diyl)-1,4-phenylene]) (PIF8-TAA), poly[[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl]] (PTB7), poly[N-90-heptadecanyl-2,7-carbazole-alt-5,5-(40,70-di-2-thienyl-20,10,30-benzothiadiazole)] (PCDTBT), Poly[2,5-bis(2-decyldodecyl)pyrrolo[3,4-c]pyrrole-1,4(2H,5H)-dione-(E)-1,2-di(2,20-bithiophen-5-yl) ethene] (PDPPDBTE), 4,8-dithien-2-yl-benzo[1,2-d;4,5-d′]bistriazole-alt-benzo[1,2-b:4,5b′]dithiophenes (pBBTa-BDTs), pBBTa-BDT1, pBBTa-BDT2 polymers, poly(3-hexylthiophene) (P3HT), poly(4,4′-bis(N-carbazolyl)-1,1′-biphenyl) (PPN), triarylamine (TAA) and/or thiophene moieties, Paracyclophane, Triptycene, and Bimesitylene, Thiophene and Furan-based hole transport materials, Dendrimer-like and star-type hole transport materials, VO, VOX, MoC, WO, ReO, NiOx, AgOx, CuO, Cu2O, V2O5, CuI, CuS, CuInS2, colloidal quantum dots, lead sulphide (PbS), CuSCN, Cu2ZnSnS4, Au nanoparticles and their derivatives. Thiophene derivatives, Triptycene derivatives, Triazine derivatives, Porphyrin derivatives, Triphenylamine derivatives, Tetrathiafulvalene derivatives, Carbazole derivatives and Phthalocyanine derivatives. As used herein, when a material is referred to a “derivate” or as “derivatives,” such as Triphenylamine derivatives, the material contains Triphenylamine in its backbone structure. In certain embodiments, the charge transport layer between the perovskite composition and the cathode (hole transport layer) is selected from the group consisting of PTAA, Poly-TPD, Spiro-OMeTAD, PEDOT:PSS, NiO, MoO3, V2O5, EH44, and a combination thereof.

In certain embodiments, the charge transport layer between perovskite composition and the anode (electron transport layer) comprises at least one of LiF, CsP, LiCoO, CsCO, TiO_{X}, TiO, nanorods (NRs), ZnO, ZnO nanorods (NRs), ZnO nanoparticles (NPs), ZnO, Al—O, CaO, bathocuproine (BCP), copper phthalocyanine (CuPc), pentacene, pyronin B, pentadecafluorooctyl phenyl-C60-butyrate (F-PCBM), C60, C60/LiF, ZnO NRS/PCBM, ZnO/cross-linked fullerene derivative (C-PCBSD), single walled carbon nanotubes (SWCNT), poly(ethylene glycol) (PEG), poly(dimethylsiloxane-block-methyl methacrylate) (PDMS-b-PMMA), polar polyfluorene (PF-EP), polyfluorene bearing lateral amino groups (PFN), polyfluorene bearing quaternary ammonium groups in the side chains (WPF-oxy-F), polyfluorene bearing quaternary ammonium groups in the side chains (WPF-6-oxy-F), fluorene alternating and random copolymer bearing cationic groups in the alkyl side chains (PFNBr DBT15), fluorene alternating and random copolymer bearing cationic groups in the alkyl side chains (PFPNBr), poly (ethylene oxide) (PEO), and fullerene derivatives. In certain embodiments, the charge transport layer between perovskite composition and the anode (electron transport layer) is selected from the group consisting of C60, BCP, TiO2, SnO2, PCBM, ICBA, ICMA, ZnO, ZrAcac, LiF, TPBI, PFN, and a combination thereof.

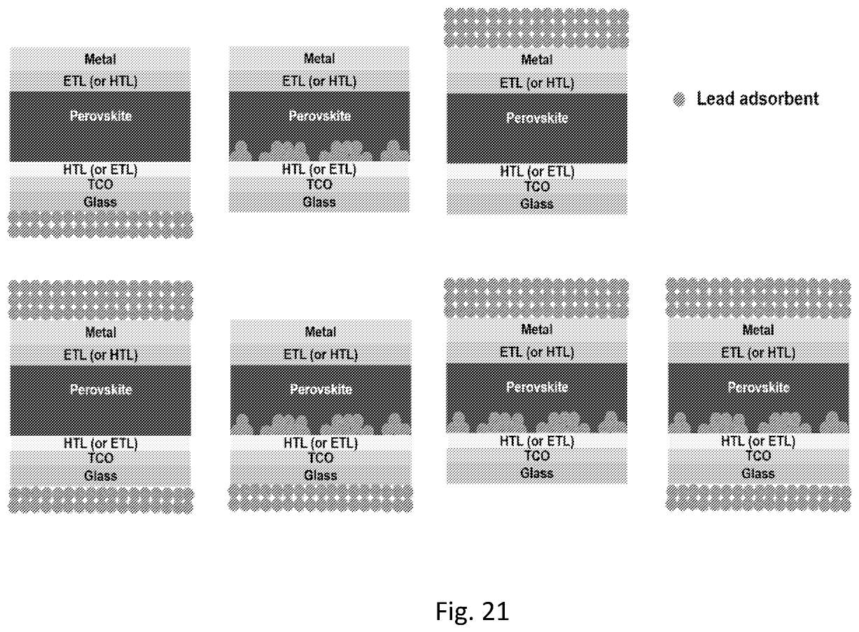

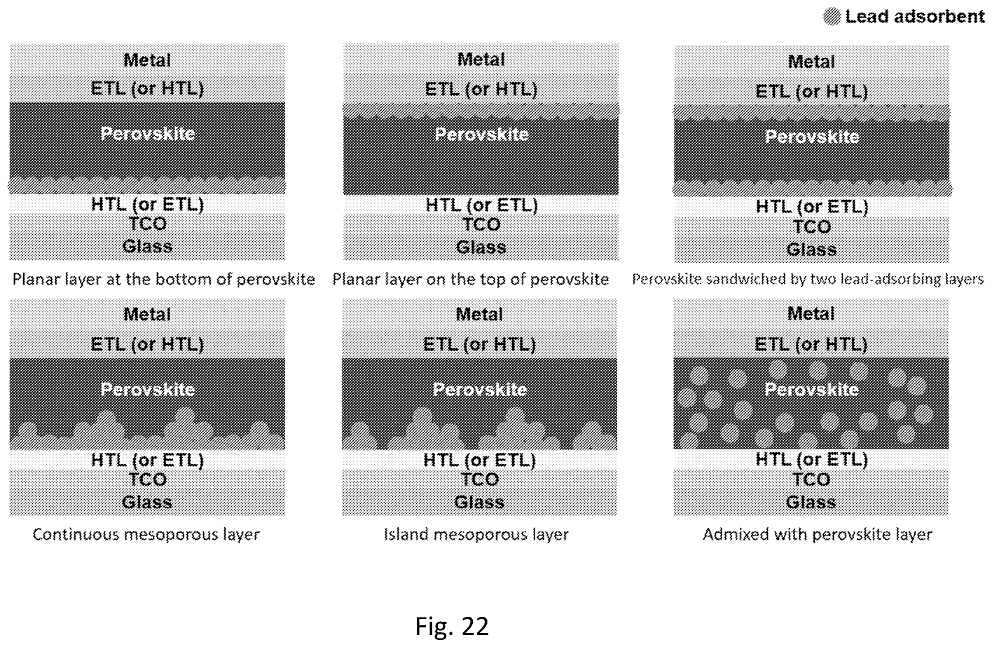

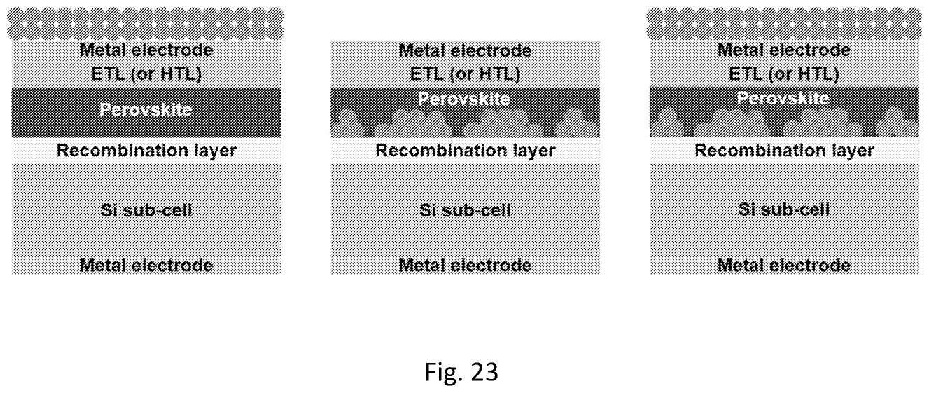

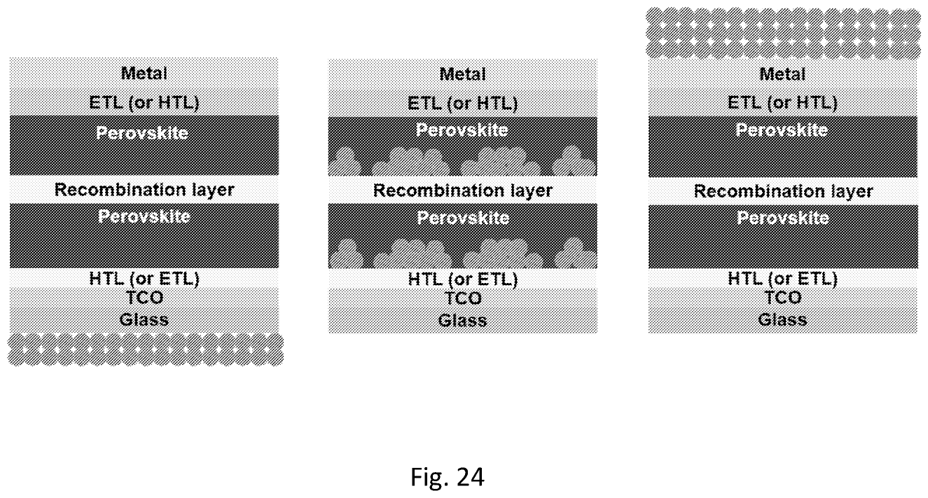

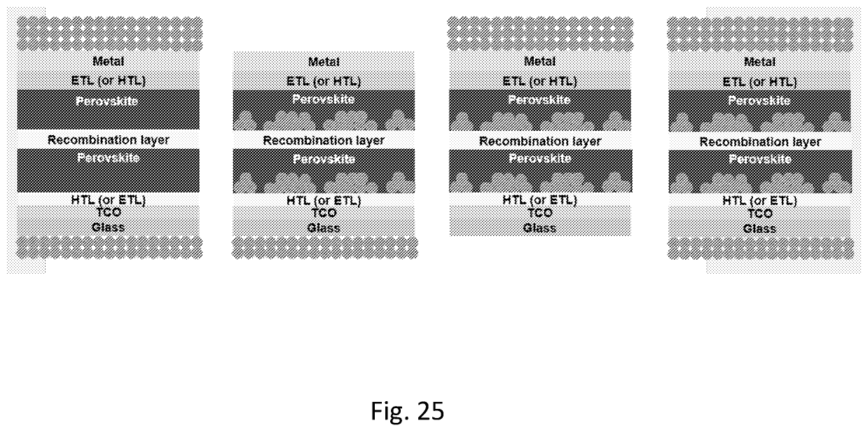

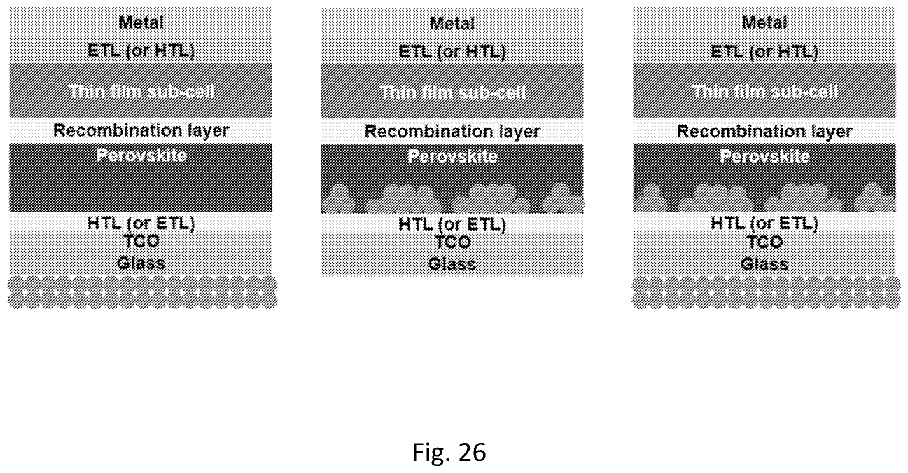

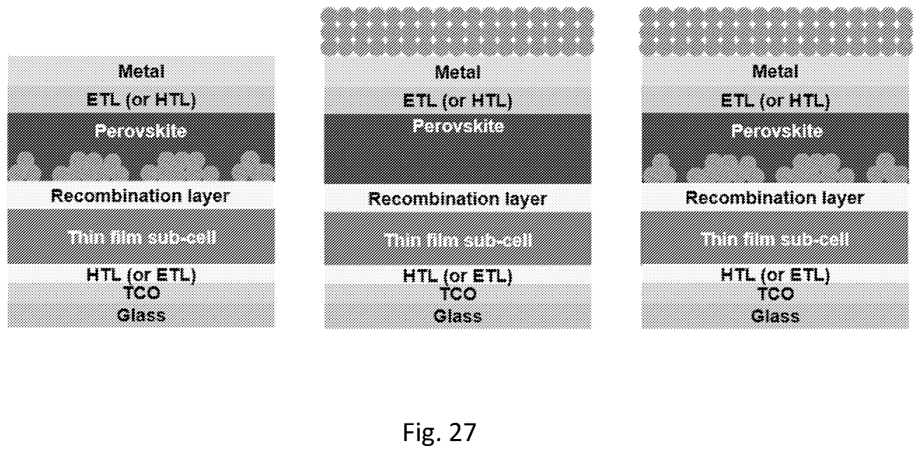

The location of the lead-absorbing material in the solar cell is not limited to any particular layer or material within the cell. The lead-absorbing material can be distributed anywhere in the cell. Additionally, the lead-absorbing material may reside in several places simultaneously throughout the cell. Non-limiting examples displaying the distribution of the lead-absorbing material are provided in FIG. 21 and FIG. 22 for single-junction solar cells. In certain embodiments, the lead-absorbing material described herein may be incorporated into perovskite tandem solar cells or solar modules, including monolithic, mechanically-stacked, or spectrally-split cells. Non-limiting examples displaying the distribution of the lead-absorbing material are provided in FIG. 23 for tandem perovskite silicon solar cells, FIG. 24 and FIG. 25 for perovskite/perovskite tandem solar cells, and FIG. 26 and FIG. 27 for perovskite/thin film tandem cells. In embodiments, the perovskite tandem solar module can be a perovskite-perovskite tandem solar module, a perovskite/silicon tandem module, or a perovskite/copper-indium-gallium-selenide tandem module.

In certain embodiments, the solar cells further comprise a glass layer, wherein the transparent conductive oxide layer is disposed directly on the glass layer. In certain embodiments, the glass is used to encapsulate the solar cell. The glass layer comprises silica (SiO₂). In certain aspects, the solar cells comprise a first glass layer and a second glass layer, wherein the conductive oxide layer is disposed on said first glass layer and said second glass layer is disposed on said conductive electrode. In certain embodiments, the glass layer has a thickness of about 1.1 mm. In certain embodiment, the glass layer has a thickness of about 0.5, 0.6, 0.7, 0.8, 0.9, 1.0, 1.1, 1.2, 1.3, 1.4, or 1.5 mm. In certain embodiments, the glass encapsulates the solar cell or solar module by coating the edges of the glass with epoxy and contacting them with the cell or module.

In certain embodiments, the back of the solar cell or solar module is encapsulated with a polymer. As used herein, the “the back of the solar cell or solar module” or “backside” refers to the side of the cell or module that is shaded, largely facing away from the light source. The polymer can be any polymer sheet sealed by encapsulant, or ethylene-vinyl acetate copolymer (EVA), polypropylene, polyolefin (POE), ethylene-propylene-diene monomer (EPDM), or cross-linkable encapsulants that can be laminated to the back of solar the cell or solar module. In certain embodiments, the polymer that encapsulates the back of the solar cell or the solar module is a polymer sheet or board. In one embodiment, the polymer is polypropylene. In certain embodiments, the back of the solar cell or solar module is encapsulated with a polypropylene board. In certain embodiment, the polypropylene board has a thickness of about 0.5, 0.6, 0.7, 0.8, 0.9, 1.0, 1.1, 1.2, 1.3, 1.4, or 1.5 mm. In certain embodiments, the polypropylene board encapsulates the solar cell or solar module by coating the edges of the board with epoxy and contacting them with the cell or module.

In certain embodiments, the lead absorbing material is in a lead absorbing material layer. The solar cells can comprise any number of layers comprising the lead absorbing material layer. In certain embodiments, the solar cells comprise one, two, or three layers comprising the lead absorbing material layer. In certain embodiments, the lead absorbing material layer is in a lead absorbing material layer, wherein the glass layer is disposed directly on the lead absorbing material layer.

In certain embodiments, the lead absorbing material layer comprises a first layer in the solar cell; the glass layer comprises a second layer, wherein the glass layer is disposed directly on the lead-absorbing layer; the transparent conductive oxide layer comprises a third layer in the solar cell, wherein the transparent conductive oxide layer is disposed directly on the glass layer; the first transport layer comprises a fourth layer in the solar cell, wherein the first transport layer is disposed directly on the transparent conductive oxide layer; the perovskite composition comprises a fifth layer in the solar cell, wherein the perovskite composition is disposed directly on the first transport layer; the second transport layer comprises a sixth layer in the solar cell wherein the second transport layer is disposed directly on the perovskite layer; and the metal electrode comprises a seventh layer in the solar cell, wherein the metal electrode is disposed directly on the second transport layer.

In certain embodiments, the lead-absorbing material is in the perovskite composition layer. In certain embodiments, the lead-absorbing material can be admixed with the perovskite composition. In certain embodiments, the lead-absorbing material can form a planar layer at the bottom of the perovskite composition layer. In certain embodiments, the lead-absorbing material can form a planar layer at the top of the perovskite composition layer, below the deposition of the second transport layer. In certain embodiments, the lead-absorbing material can form a planar layer both at the top and at the bottom of the perovskite composition layer. In certain embodiments, the lead-absorbing material forms a continuous mesoporous layer within the perovskite composition layer. In certain embodiments of the lead-absorbing material that forms a continuous mesoporous layer within the perovskite composition layer, the lead-absorbing material forms a continuous mesoporous layer within the bottom 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, or 25% of the perovskite composition layer. In certain embodiments, the lead-absorbing material forms an island mesoporous layer within the perovskite composition layer.

In certain embodiments, the glass layer comprises a first layer in the solar cell; the transparent conductive oxide layer comprises a second layer in the solar cell, wherein the transparent conductive oxide layer is disposed directly on the glass layer; the first transport layer comprises a third layer in the solar cell, wherein the first transport layer is disposed directly on the transparent conductive oxide layer; the lead absorbing material layer forms a fourth layer in the solar cell, which is disposed on the first transport layer and forms a mesoporous layer within the perovskite composition, which comprises a fifth layer in the solar cell; the second transport layer comprises a sixth layer in the solar cell, wherein the second transport layer is disposed directly on the perovskite layer; and the metal electrode comprises a seventh layer in the solar cell, wherein the metal electrode is disposed directly on the second transport layer.

In certain embodiments, the glass layer comprises a first layer in the solar cell; the transparent conductive oxide layer comprises a second layer in the solar cell, wherein the transparent conductive oxide layer is disposed directly on the glass layer; the first transport layer comprises a third layer in the solar cell, wherein the first transport layer is disposed directly on the transparent conductive oxide layer; the perovskite composition comprises a fourth layer in the solar cell, wherein the perovskite composition is disposed directly on the first transport layer; the second transport layer comprises a fifth layer in the solar cell wherein the second transport layer is disposed directly on the perovskite layer; the metal electrode comprises a sixth layer in the solar cell, wherein the metal electrode is disposed directly on the second transport layer; and the lead absorbing material layer comprises a seventh layer in the solar cell, wherein the lead absorbing layer is disposed directly on the metal electrode.

In certain embodiments, the lead absorbing material layer comprises a first layer in the solar cell; the glass layer comprises a second layer, wherein the glass layer is disposed directly on the lead-absorbing layer; the transparent conductive oxide layer comprises a third layer in the solar cell, wherein the transparent conductive oxide layer is disposed directly on the glass layer; the first transport layer comprises a fourth layer in the solar cell, wherein the first transport layer is disposed directly on the transparent conductive oxide layer; the perovskite composition comprises a fifth layer in the solar cell, wherein the perovskite composition is disposed directly on the first transport layer; the second transport layer comprises a sixth layer in the solar cell wherein the second transport layer is disposed directly on the perovskite layer; the metal electrode comprises a seventh layer in the solar cell, wherein the metal electrode is disposed directly on the second transport layer; and a second lead absorbing material layer comprises a seventh layer in the solar cell, wherein the second lead absorbing material layer is disposed directly on the metal electrode.

In certain embodiments, the lead absorbing material layer comprises a first layer in the solar cell; the glass layer comprises a second layer, wherein the glass layer is disposed directly on the lead-absorbing layer; the transparent conductive oxide layer comprises a third layer in the solar cell, wherein the transparent conductive oxide layer is disposed directly on the glass layer; the first transport layer comprises a fourth layer in the solar cell, wherein the first transport layer is disposed directly on the transparent conductive oxide layer; a second lead absorbing material layer comprises a fifth layer in the solar cell, which is disposed on the first transport layer and forms a mesoporous layer within the perovskite composition, which comprises a sixth layer in the solar cell; the second transport layer comprises a seventh layer in the solar cell, wherein the second transport layer is disposed directly on the perovskite layer; and, the metal electrode comprises an eighth layer in the solar cell, wherein the metal electrode is disposed directly on the second transport layer.

In certain embodiments, the glass layer comprises a first layer in the solar cell; the transparent conductive oxide layer comprises a second layer in the solar cell, wherein the transparent conductive oxide layer is disposed directly on the glass layer; the first transport layer comprises a third layer in the solar cell, wherein the first transport layer is disposed directly on the transparent conductive oxide layer; the lead absorbing material forms a fourth layer in the solar cell, which is disposed on the first transport layer and forms a mesoporous layer within the perovskite composition, which comprises a fifth layer in the solar cell; the second transport layer comprises a sixth layer in the solar cell wherein the second transport layer is disposed directly on the perovskite layer; the metal electrode comprises a seventh layer in the solar cell, wherein the metal electrode is disposed directly on the second transport layer; and a second lead absorbing material comprises an eight layer in the solar cell, wherein the second lead absorbing material layer is disposed directly on the metal electrode.

In certain embodiments, the lead absorbing material layer comprises a first layer in the solar cell; the glass layer comprises a second layer, wherein the glass layer is disposed directly on the lead-absorbing layer; the transparent conductive oxide layer comprises a third layer in the solar cell, wherein the transparent conductive oxide layer is disposed directly on the glass layer; the first transport layer comprises a fourth layer in the solar cell, wherein the first transport layer is disposed directly on the transparent conductive oxide layer; a second lead absorbing material comprises a fifth layer in the solar cell, which is disposed on the first transport layer and forms a mesoporous layer within the perovskite composition, which comprises the sixth layer in the solar cell; the second transport layer comprises a seventh layer in the solar cell wherein the second transport layer is disposed directly on the perovskite layer; the metal electrode comprises an eighth layer in the solar cell, wherein the metal electrode is disposed directly on the second transport layer; and a third lead absorbing material layer comprises a ninth layer in the solar cell, wherein the third lead absorbing material layer is disposed directly on the metal electrode.

In any of the above embodiments, the lead absorbing material can be disposed directly on the perovskite composition, wherein the second transport layer is disposed directly on the lead absorbing material layer.

In any of the above embodiments, the lead absorbing material layer can be disposed on the first transport layer, wherein the perovskite composition is disposed directly on the lead absorbing material layer; and another lead absorbing material layer can be disposed directly on the perovskite composition, wherein the second transport layer is disposed directly on the second lead absorbing material layer.

In any of the above embodiments, the first transport layer is a hole transport layer and the second transport layer is an electron transport layer. In certain embodiments, the first transport layer is an electron transport layer and the second transport layer is a hole transport layer.

In any of the embodiments above wherein the first transport layer is a hole transport layer and the second transport layer is an electron transport layer, the solar cell further comprises a buffer layer disposed directly on the electron transport layer, wherein the metal electrode is disposed directly on the buffer layer. In certain embodiments, the buffer layer is selected from the group consisting of PDI, PDINO, PFN, PFN—Br, SnO₂, ZnO, ZrAcac, TiO₂, BCP, LiF, PPDIN6, and TPBi In certain embodiments, the buffer layer is BCP.

In certain embodiments, the subject matter disclosed herein is directed to a solar cell comprising: a first transport layer and a second transport layer; wherein: the first transport layer is disposed directly on the transparent conductive oxide layer; the perovskite composition is disposed on the first transport layer; the second transport layer is disposed on the perovskite composition; and the metal electrode is disposed on the second transport layer; and,

wherein the solar cell further comprises a glass layer, wherein the transparent conductive oxide layer is disposed directly on the glass layer. In certain aspects of this embodiment, the lead absorbing material is in a lead absorbing material layer, wherein the lead absorbing material layer is disposed directly on the metal electrode.

In certain embodiments of the above embodiment, the transparent conductive oxide layer is ITO, the first transport layer is PTAA, the perovskite composition is MAPbI₃, the second transport layer comprises C60; the solar cell further comprises a buffer layer comprising BCP, wherein the first layer of C60 is disposed directly on the perovskite composition and the buffer layer comprising BCP is disposed directly on the layer of C60; the metal electrode is copper, wherein the metal electrode is disposed directly on the layer of BCP; and the lead absorbing material is crosslinked sodium polystyrene sulphonate, wherein the lead absorbing material is disposed directly on the metal electrode.

The subject matter disclosed herein is further directed to solar modules. In one aspect, the subject matter is directed to a plurality of solar cells of the above embodiment, which comprise a solar module. In certain embodiments, the solar cell has an area of about 95 cm², 99 cm², 100 cm², 101 cm², 102 cm², 103 cm², 104 cm², 105 cm², 106 cm², 107 cm², or 108 cm².

In certain embodiments, the subject matter disclosed herein is directed to a solar cell comprising: a first transport layer and a second transport layer; wherein: the first transport layer is disposed directly on the transparent conductive oxide layer; the perovskite composition is disposed on the first transport layer; the second transport layer is disposed on the perovskite composition; and the metal electrode is disposed on the second transport layer; and,

wherein the solar cell further comprises a glass layer, wherein the transparent conductive oxide layer is disposed directly on the glass layer. In certain embodiments, the lead absorbing material is in a first lead absorbing material layer and a second lead absorbing material layer, wherein the glass layer is disposed directly on the first lead absorbing material layer, and the second lead absorbing material layer is disposed directly on the metal electrode.

In certain embodiments of the above embodiment, the first lead absorbing material layer is crosslinked sodium polystyrene sulphonate; the first transport layer is PTAA; the perovskite composition is MAPbI₃; the second transport layer comprises C60; the solar cell further comprises a buffer layer comprising BCP, wherein the first layer of C60 is disposed directly on the perovskite composition and the buffer layer comprising BCP is disposed directly on the layer of C60; the metal electrode is copper, wherein the metal electrode is disposed directly on the layer of BCP; and the second lead absorbing material layer is crosslinked sodium polystyrene sulphonate, wherein the second lead absorbing material is disposed directly on the metal electrode

The subject matter disclosed herein is further directed to solar modules. In one aspect, the subject matter is directed to a plurality of solar cells of the above embodiment, which comprise a solar module.

In certain embodiments, the subject matter described herein is directed to solar cells comprising a lead-absorbing material, a perovskite composition comprising lead, and a carbon electrode. In certain embodiments, the carbon electrode comprises a carbon paste comprising graphite and carbon black.

In certain embodiments, the lead absorbing material is admixed with the carbon electrode. In certain embodiments, the lead absorbing material is admixed with the carbon electrode in a ratio from about 1:10000 to 10:1. In certain embodiments, the the lead absorbing material is admixed with the carbon electrode in a ratio from about 1:2, 1:5, 1:10, 1:15, 1:20, 1:30, 1:50, 1:60, 1:70, 1:80, or 1:100.

In certain embodiments, the solar cells disclosed herein comprise:

a transparent conductive oxide layer; wherein the perovskite composition is disposed on the transparent conductive oxide layer; and the carbon electrode is disposed on the perovskite composition, wherein the lead absorbing material is admixed with the carbon electrode.

In certain aspects of the above embodiment, the solar cells further comprise a first transport layer; wherein the first transport layer is disposed on the transparent conductive oxide layer; the perovskite composition is disposed on the first transport layer; and the carbon electrode is disposed on the perovskite composition.

In certain aspects of the above embodiment, the solar cells further comprise a glass layer, wherein the transparent conductive oxide layer is disposed directly on the glass layer. In certain aspects, the lead absorbing material further comprises a lead absorbing material layer, wherein the glass layer is disposed directly on the lead absorbing material layer.

In certain aspects of the above embodiment, the first transport layer is an electron transport layer. In certain embodiments of this embodiment, the electron transport layer is SnO₂. In certain aspects of this embodiment, the perovskite composition is MAPbI₃. In certain aspects of this embodiment, the transparent conductive oxide layer is ITO. In certain embodiments, the subject matter disclosed herein is directed to a solar module comprising a plurality of solar cell of the above embodiment.

In certain embodiments, the solar cells disclosed herein comprise:

In certain aspects of the above embodiments comprising a carbon electrode admixed with the lead absorbing material composition, a first transport layer; wherein the first transport layer disposed on the transparent conductive oxide layer; the perovskite composition disposed on the first transport layer; and the carbon electrode disposed on the perovskite composition, the solar cells further comprise a second transport layer, wherein said second transport layer is disposed on the perovskite composition and the carbon electrode is disposed on the second transport layer.

In certain aspects of the above embodiment, the transparent conductive oxide layer is ITO; the first transport layer is PTAA; the perovskite composition is Rb_{0.05}Cs_{0.05}FA_{0.85}MA_{0.05}PbI_{2.85}Br_{0.15}; and the second transport layer comprises C₆₀ and SnO₂. In certain aspects of this embodiment, the solar cell can comprise a glass layer, wherein the transparent conductive oxide layer is disposed directly on the glass layer. In further aspects of this embodiment, said lead absorbing material further comprises a lead absorbing material layer, wherein the glass layer is disposed directly on the lead absorbing material layer.

In certain embodiments the metal electrode has a thickness of about 1 nm to about 1000 μm, about 100 nm to about 500 nm, about 1 μm to about 500 μm, about 250 μm to about 1000 μm, or about 250 nm to about 250 μm. In certain embodiments, the metal electrode has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 μm.

In certain embodiments, the transparent conductive oxide layer has a thickness of about 1 nm to about 1000 μm, about 100 nm to about 500 nm, about 1 μm to about 500 μm, about 250 μm to about 1000 μm, or about 250 nm to about 250 μm. In certain embodiments, the transparent conductive layer has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 μm.

In certain embodiments, the first and second transport layers each individually have a thickness of about 0.1 nm to about 10 μm, about 0.5 nm to about 100 nm, about 10 nm to about 500 nm, about 300 nm to about 700 nm, about 100 nm to about 1 μm, about 1 μm to about 10 m, or about 800 nm to about 5 μm. In certain embodiments, the first and second transport layers each individually have a thickness of about 0.1 nm, 0.5 nm, 1.0 nm, 2.0 nm, 5.0 nm, 10 nm, 20 nm, 30 nm, 40 nm, 50 nm, 60 nm, 70 nm, 80 nm, 90 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1 μm, 2 μm, 3 μm, 4 μm, 5 μm, 6 μm, 7 μm, 8 μm, 9 μm, or 10 μm.

In certain embodiments, when the lead absorbing material is in a lead absorbing layer, the layer has a thickness of about 0.1 nm to about 1000 μm, about 1 nm to about 500 μm, about 10 nm to about 10 μm, about 0.5 nm to about 100 nm, about 10 nm to about 500 nm, about 300 nm to about 700 nm, about 100 nm to about 1 μm, about 1 μm to about 10 μm, about 800 nm to about 5 μm, about 50 nm to about 500 μm, about 100 nm to about 1500 nm, or about 300 nm to about 1300 nm. In certain embodiments, when the lead absorbing material is in a lead absorbing layer, the layer has a thickness of about 0.1 nm, 0.5 nm, 1.0 nm, 2.0 nm, 5.0 nm, 10 nm, 20 nm, 30 nm, 40 nm, 50 nm, 60 nm, 70 nm, 80 nm, 90 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 960 nm, 970 nm, 980 nm, 990 nm, 1000 nm, 1 μm, 1.1 μm, 1.2 μm, 1.3 μm, 1.4 μm, 1.5 μm, 1.6 μm, 1.7 μm, 1.8 μm, 1.9 μm, 2 μm, 3 μm, 4 μm, 5 μm, 6 μm, 7 μm, 8 μm, 9 μm, 10 μm, 50 μm, 60 μm, 70 μm, 80 μm, 90 μm, 100 μm, 200 μm, 300 μm, 400 μm, 500 μm, 600 μm, 700 μm, 800 μm, 900 μm, or 1000 μm.

In certain embodiments, when the lead absorbing material is in a lead absorbing layer, the layer comprises mesoporous nanoparticles with a size of about 100 nm. In certain embodiments, when the lead absorbing material is in a lead absorbing layer, the layer comprises mesoporous nanoparticles with a size of about 80 nm, 85 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, or 110 nm.

The Power Conversion Efficiency (PCE) of the solar cells as described herein ranges from about 15% to about 26%. In certain embodiments, the PCE is at least 18%, 19%, 20%, 21%, 22%, 23%, or 24%. In certain embodiments, integration of the lead absorbing material improves the power conversion efficiency of the solar cell. In certain embodiments, the power conversion efficiency improves by at least 1%, 2%, 3%, 4%, 5%, 6%, 7%, 8%, 9%, or 10%.

As demonstrated herein, the lead-absorbing material layers in the solar cells help prevent lead leakage of the solar cell. In certain embodiments, the lead-absorbing material reduces lead leakage from about 15 ppm to about 2 ppm, or from about 13 ppm to about 1 ppm. In certain embodiments, the lead-absorbing material reduces lead leakage by about 2%, 5%, 6%, 7%, 8%, 9%, 10%, 11%, 12%, 13%, 14%, 15%, 16%, 17%, 18%, 19%, 20%, 21%, 22%, 23%, 24%, 25%, 30%, 35%, 40%, 45%, 50%, 55%, 60%, 65%, 70%, 75%, 80%, 81%, 82%, 83%, 84%, 85%, 86%, 87%, 88%, 89%, 90%, 91%, 92%, 93%, 94%, 95%, 96%, 99%, or 100%.

The subject matter described herein is directed to the following embodiments:

1. A solar cell, comprising:
an active layer comprising a perovskite composition, wherein said perovskite composition comprises lead; and
a lead absorbing material, wherein said lead absorbing material does not comprise:
   P,P′-di(2-ethylhexyl)methanediphosphonic acid; enediaminetetrakis(methylenephosphonic acid); or tetraethylene glycol-substituted 2,1,3-benzothiadiazole.
      2. The solar cell of embodiment 1, wherein said lead absorbing material is a neutral molecule that can form a complex with lead.
      3. The solar cell of embodiment 1 or 2, wherein said neutral molecule is selected from the group consisting of crown ether, cyclodextrin, porphyrin, calixarene, calixcarbazole, pillararene, and cucurbituril.
      4. The solar cell of embodiment 1, wherein said lead absorbing material is an ion exchange material.
      5. The solar cell of embodiment 4, wherein said ion exchange material comprises a negatively-charged functional group selected from the group consisting of SO₃²⁻ (sulfite), SO₃⁻ (sulfonate), SO₄²⁻ (sulfate), C₆H₅O₇⁻³ (citrate), C₄H₄O₆²⁻ (tartrate), PO₄³⁻ (phosphate), CO₃²⁻ (carbonate), AsO₄³⁻ (arsenate), ClO₄⁻ (perchlorate), SCN⁻ (thiocyanate), S₂O₃²⁻ (thiosulfate), WO₄²⁻ (tungstate), MoO₄²⁻ (molybdate), CrO₄²⁻ (chromate), C₂O₄²⁻ (oxalate), HSO₄⁻ (hydrogen sulfate), HPO₄²⁻ (hydrogenphosphate), NO₃⁻ (nitrate), NO₂⁻ (nitrite), CN⁻ (cyanide), Cl⁻ (chloride), HCO₃⁻ (bicarbonate), H₂PO₄⁻ (dihydrogenphosphate), CH₃COO⁻ (acetate), IO₃⁻ (iodate), HCOO⁻ (formate), BrO₃⁻ (bromate), ClO₃⁻ (chlorate), F⁻ (fluoride), and OH⁻ (hydroxide).
      6. The solar cell of embodiment 4 or 5, wherein said ion exchange material comprises a sulfonate functional group.
      7. The solar cell of any one of embodiments 1, 4, 5, or 6, wherein said ion exchange material is a polystyrene sulphonate.
      8. The solar cell of embodiment 7, wherein said polystyrene sulphonate is a crosslinked polystyrene sulphonate.
      9. The solar cell of embodiment 8, wherein said crosslinked polystyrene sulphonate is selected from the group consisting of crosslinked calcium polystyrene sulphonate, crosslinked hydrogen polystyrene sulphonate, crosslinked sodium polystyrene sulphonate, and crosslinked potassium polystyrene sulphonate.
      10. The solar cell of embodiment 8 or 9, wherein said crosslinked polystyrene sulphonate is crosslinked sodium polystyrene sulphonate.
      11. The solar cell of embodiment 1, wherein said perovskite composition has a formula of ABX₃,

where A is a cation selected from the group consisting of methylammonium (MA), tetramethylammonium, formamidinium (FA), cesium, rubidium, potassium, sodium, calcium, butylammonium, phenethylammonium, phenylammonium, guanidinium, ammonium, and a combination thereof,

B is a metal cation comprising lead; and

X is selected from the group consisting of chloride, bromide, fluoride, iodide, thiocyanate, and a combination thereof.

12. The solar cell of embodiment 11, wherein said perovskite composition is selected from the group consisting of MAPbI₃, MAPbBr₃, and MAPbCl₃.
13. The solar cell of embodiment 11, wherein A is selected from the group consisting of Cs, FA, MA, Rb, and a combination thereof, B is lead; and X is selected from the group consisting of iodide, bromide, and a combination thereof.
14. The solar cell of embodiment 11 or 13, wherein said perovskite composition is RbₓCs_{y}FA_{1-x-y-z}MA_{z}PbI_{3-f}Br_{f}((x+y+z)<1; f<3).
15. The solar cell of any one of embodiments 11, 13 or 14, wherein said perovskite composition is Rb_{0.05}Cs_{0.05}FA_{0.85}MA_{0.05}PbI_{2.85}Br_{0.15}.
16. The solar cell of embodiment 1, further comprising:

a transparent conductive oxide layer and a metal electrode; wherein:

said perovskite composition is disposed on said transparent conductive oxide layer and said metal electrode is disposed on said perovskite composition.

17. The solar cell of embodiment 16, further comprising:

a first transport layer and a second transport layer; wherein:

said first transport layer is disposed directly on said transparent conductive oxide layer;

said perovskite composition is disposed on said first transport layer;

said second transport layer is disposed on said perovskite composition; and said metal electrode is disposed on said second transport layer.

17a. The solar cell of embodiment 1, further comprising:

a first transparent conductive oxide layer and a second transparent conductive oxide layer; wherein:

said perovskite composition is disposed on said first transparent conductive oxide layer and said second transparent conductive oxide layer is disposed on said perovskite composition.

17b. The solar cell of embodiment 17a, wherein said lead absorbing material is in a lead absorbing material layer, wherein said lead absorbing material layer is disposed on said second transparent conductive oxide layer or said first transparent conductive oxide layer is disposed on said lead absorbing material layer.
18. The solar cell of embodiment 17, 17a, or 17b, further comprising a glass layer, wherein said transparent conductive oxide layer is disposed directly on said glass layer.
19. The solar cell of embodiment 18, wherein said lead absorbing material is in a lead absorbing material layer, wherein said glass layer is disposed directly on said lead absorbing material layer.
20. The solar cell of embodiment 18, wherein said lead absorbing material is in a lead absorbing material layer, wherein said lead absorbing material layer is disposed directly on said first transport layer, and said perovskite composition is disposed directly on said lead absorbing material layer.
21. The solar cell of embodiment 18, wherein said lead absorbing material is admixed with said perovskite composition.
22. The solar cell of embodiment 18, wherein said lead absorbing material is in a lead absorbing material layer, wherein lead absorbing material layer is disposed directly on said metal electrode.
23. The solar cell of embodiment 18, wherein said lead absorbing material is in a first lead absorbing material layer and a second lead absorbing material layer;

wherein said glass layer is disposed directly on said first lead absorbing material layer, and

said second lead absorbing material layer is disposed directly on said metal electrode.

24. The solar cell of embodiment 18, wherein said lead absorbing material is in a first lead absorbing material layer and a second lead absorbing material layer;

wherein said glass layer is disposed directly on said first lead absorbing material layer; and

said second lead absorbing material layer is disposed directly on said first transport layer, wherein said perovskite composition is disposed directly on said second lead absorbing material layer.

25. The solar cell of embodiment 18, wherein said lead absorbing material is in a first lead absorbing material layer and a second lead absorbing material layer;

wherein said first lead absorbing material layer is disposed directly on said first transport layer, wherein said perovskite composition is disposed directly on said first lead absorbing material layer; and

said second lead absorbing material layer is disposed directly on said metal electrode.

26. The solar cell of embodiment 18, wherein said lead absorbing material is in a first lead absorbing material layer and a second lead absorbing material layer;

wherein said first lead absorbing material layer is disposed directly on said first transport layer, wherein said perovskite composition is disposed directly on said first lead absorbing material layer, and;

said second lead absorbing material layer is disposed directly on said perovskite composition, wherein said second transport layer is disposed directly on said second lead absorbing material layer.

27. The solar cell of embodiment 18, wherein said lead absorbing material is in a lead absorbing material layer, wherein:

said lead absorbing material layer is disposed directly on said perovskite composition, wherein said second transport layer is disposed directly on said lead absorbing material layer.

28. The solar cell of embodiment 18, wherein said lead absorbing material is in a first lead absorbing material layer, a second lead absorbing material layer, and a third lead absorbing material layer, wherein:

said glass layer is disposed directly on said first lead absorbing material layer;

said second lead absorbing material layer is disposed directly on said first transport layer, wherein said perovskite composition is disposed directly on said second lead absorbing material layer; and

said third lead absorbing material layer is disposed directly on said metal electrode.

29. The solar cell of any one of embodiments 16-28, wherein said transparent conductive oxide layer is selected from the group consisting of ITO, FTO, ZITO, and AZO.
30. The solar cell of any one of embodiments 16-28, wherein said metal electrode is selected from the group consisting of Al, Au, Cu, Cr, Ca, Mg, Bi, Ag, and Ti.
31. The solar cell of any one of embodiments 17-28, wherein said first transport layer is a hole transport layer and said second transport layer is an electron transport layer.
32. The solar cell of embodiment 31, wherein said hole transport layer is selected from the group consisting of PTAA, Poly-TPD, Spiro-OMeTAD, PEDOT:PSS, NiO, MoO3, V2O5, EH44, and a combination thereof.
33. The solar cell of embodiment 31, wherein said electron transport layer is selected from the group consisting of C60, BCP, TiO₂, SnO₂, PCBM, ICBA, ICMA, ZnO, ZrAcac, LiF, TPBI, PFN, and a combination thereof.
34. The solar cell of any one of embodiments 31-33, wherein said solar cell further comprises a buffer layer disposed directly on said electron transport layer, wherein said metal electrode is disposed directly on said buffer layer.
35. The solar cell of any one of embodiments 1-34, wherein said transparent conductive oxide layer is ITO, said first transport layer is PTAA, said perovskite composition is MAPbI₃, said second transport layer comprises C60; said solar cell further comprises a buffer layer comprising BCP, wherein said first layer of C60 is disposed directly on said perovskite composition and said buffer layer comprising BCP is disposed directly on said layer of C60; said metal electrode is copper, wherein said metal electrode is disposed directly on said layer of BCP; and said lead absorbing material is crosslinked sodium polystyrene sulphonate, wherein said second lead absorbing material is disposed directly on said metal electrode.
36. A solar module, comprising a plurality of the solar cell of any one of embodiments 16-35.
37. The solar module of embodiment 36, having an area of about 102 cm².
38. The solar cell of any one of embodiments 1-34, wherein said first lead absorbing material layer is crosslinked sodium polystyrene sulphonate; said first transport layer is PTAA; said perovskite composition is MAPbI₃; said second transport layer comprises C60; said solar cell further comprises a buffer layer comprising BCP, wherein said first layer of C60 is disposed directly on said perovskite composition and said buffer layer comprising BCP is disposed directly on said layer of C60; said metal electrode is copper, wherein said metal electrode is disposed directly on said layer of BCP; and second lead absorbing material layer is crosslinked sodium polystyrene sulphonate, wherein said second lead absorbing material is disposed directly on said metal electrode.
39. A solar module, comprising a plurality of the solar cell of embodiment 38.
40. The solar cell of embodiment 1, further comprising a carbon electrode.
41. The solar cell of embodiment 40, wherein said carbon electrode comprises a carbon paste comprising graphite and carbon black.
42. The solar cell of embodiment 40 or 41, wherein said lead absorbing material is admixed with said carbon electrode.
43. The solar cell of embodiment 42, wherein said lead absorbing material is admixed with said carbon electrode in a ratio from 1:10000 to 10:1.
44. The solar cell of embodiment 42 or 43, wherein said lead absorbing material is admixed with said carbon electrode in a 1:5 ratio.
45. The solar cell of any one of embodiments 40-44, further comprising:

a transparent conductive oxide layer; wherein said perovskite composition is disposed on said transparent conductive oxide layer; and

said carbon electrode is disposed on said perovskite composition.

46. The solar cell of embodiment 45, further comprising:

a first transport layer; wherein said first transport layer is disposed on said transparent conductive oxide layer;

said perovskite composition is disposed on said first transport layer; and

said carbon electrode is disposed on said perovskite composition.

47. The solar cell of embodiment 46, further comprising a glass layer, wherein said transparent conductive oxide layer is disposed directly on said glass layer.
48. The solar cell of embodiment 47, wherein said lead absorbing material further comprises a lead absorbing material layer, wherein said glass layer is disposed directly on said lead absorbing material layer.
49. The solar cell of embodiment 46, wherein said first transport layer is an electron transport layer.
50. The solar cell of embodiment 49, wherein said electron transport layer is SnO₂.
51. The solar cell of embodiment 46, wherein said perovskite composition is MAPbI₃.
52. The solar cell of embodiment 46, wherein said transparent conductive oxide layer is ITO.
53. A solar module, comprising a plurality of the solar cell of any one of embodiments 46-52.
54. The solar cell of embodiment 46, further comprising a second transport layer, wherein said second transport layer is disposed on said perovskite composition and said carbon electrode is disposed on said second transport layer.
55. The solar cell of embodiment 54, wherein said transparent conductive oxide layer is ITO; said first transport layer is PTAA; said perovskite composition is Rb_{0.05}Cs_{0.05}FA_{0.85}MA_{0.05}PbI_{2.85}Br_{0.15}; and said second transport layer comprises C₆₀ and SnO₂.
56. The solar cell of any one of embodiments 16-55, further comprising a first glass layer and a second glass layer, wherein said conductive oxide layer is disposed on said first glass layer and said second glass layer is disposed on said conductive electrode.
57. The solar cell of embodiment 56, wherein said glass layer is about 1.1 mm.
58. The solar cell of any one of embodiments 16-57, wherein said metal electrode has a thickness of about 1 nm to about 1000 μm.
59. The solar cell of any one of embodiments 16-58, wherein said transparent conductive oxide layer has a thickness of about 1 nm to about 1000 μm.
60. The solar cell of any one of embodiments 17-59, wherein said first transport layer and said second transport layer each have a thickness of about 0.1 nm to about 10 μm.
61. The solar cell of any one of embodiments 1-60, wherein when said lead absorbing material is in a lead absorbing layer, said layer has a thickness of about 0.1 nm to about 1000 μm.
62. The solar cell of any one of embodiments 1-61, wherein said solar cell is a single junction solar cell.
63. The solar cell of any one of embodiments 1-17, wherein said solar cell is a tandem solar cell.
64. The solar cell of any one of embodiments 1-63, further comprising a polymer encapsulation.
65. The solar cell of embodiment 64, wherein said polymer encapsulation is affixed to the backside of said solar cell.
66. The solar cell of any one of embodiments 1-65, wherein said polymer encapsulation comprises polypropylene.
67. The solar module of any one of embodiments 36, 37, 39, or 53, further comprising a polymer encapsulation.
68. The solar module of embodiment 67, wherein said polymer encapsulation is affixed to the backside of said solar module.
69. The solar module of embodiment 67 or 68, wherein said polymer encapsulation comprises polypropylene.

The following examples are offered by way of illustration and not by way of limitation.

### EXAMPLES

### Methods and Materials

Materials. Cation exchange resins (Amberlyst 15, hydrogen form), poly(bis(4-phenyl)(2,4,6-trimethylphenyl)amine) (PTAA, average M, 7,000-10,000), bathocuproine (BCP), lead iodide (PbI₂, 99.999% trace metals), lead bromide (PbBr₂, 99.999% trace metals basis), Cesium iodide (CsI), rubidium iodide (RbI), N,N-dimethylformamide (DMF), dimethyl Sulfoxide (DMSO), 2-methoxyethanol (2-ME), toluene, chlorobenzene, lead standard solution (1000±2 ppm), and propylene glycol methyl ether acetate (PGMEA) were purchased from Sigma-Aldrich and used without further purification. Tin(IV) oxide, 15% in H₂O colloidal dispersion was purchased from Alfa Aesa. Methylammonium iodide (MAI), methylammonium bromide (MABr) and formamidinium iodide (FAI) were purchased from GreatCell Solar.

Fabrication of perovskite solar cells and perovskite solar modules. Patterned ITO glass substrates (1.5 cm×1.5 cm for solar cells, and 13.0 cm×8.5 cm for solar modules) were first cleaned by ultrasonication with soap, DI water, and IPA. For MAPbI₃ perovskite solar cells, the hole transport layer PTAA with a concentration of 2 mg mL⁻¹ dissolved in toluene was spin-coated onto ITO glass substrates at the speed of 6,000 rpm for 30 s and then annealed at 100° C. for 5 min. The MAPbI₃ precursor solution was prepared by dissolving PbI₂:MAI=1:1 with a concentration of 1.35 M into a mixed solvent of DMF/DMSO (9:1). To improve the wetting property of the perovskite precursor on the PTAA film, the PTAA-coated ITO substrate was pre-wetted by spinning 50 μL DMF at 4,000 rpm for 8 s. Then, 40 μL precursor solution was spun onto substrates at 2,000 rpm for 2 s and 4,000 rpm for 20 s, and was quickly washed with 130 μL toluene at the 7^{th} second of the spin-coating. Subsequently, the films were annealed at 65° C. for 10 min and 100° C. for 10 min. The devices were completed by thermally evaporating C₆₀ (30 nm, 0.2 Å s⁻¹), BCP (6 nm, 0.1 Å s⁻¹) and copper (90 nm, 1 Å s⁻¹) in a sequential order. The device active area was 8 mm². The perovskite solar modules were fabricated following a previously reported procedure (Deng, Y. et al. Sci. Adv. 5, eaax7537, (2019)). For carbon-based perovskite solar cells, the 1.2 M Rb_{0.05}Cs_{0.05}FA_{0.85}MA_{0.05}PbI_{2.85}Br_{0.15} precursor solution was dissolved in DMF/DMSO (4:1), and then spin-coated onto PTAA-covered substrates at a spin rate of 2,000 rpm for 2 s and 4,000 rpm for 20 s and dripped with 130 μL chlorobenzene at the 17^{th} second of the spin-coating. Subsequently, the films were annealed at 110° C. for 10 min, followed by evaporating 35 nm-thick C₆₀ at a rate of 0.2 Å s⁻¹. 15-nm thick SnO₂ was prepared on C₆₀ with a low-temperature atomic layer deposition (LT-ALD) method by an Ultratech/Cambridge Nanotech Savannah S200 system under a base pressure of ˜0.1 Torr. Tetrakis(dimethylamino)tin(IV) (60° C.) and H₂O (25° C.) were used as precursors for SnO₂ fabrication. The dosing sequences (t1, t2, t3, t4), where t1 and t3 refer to the times of precursor- and oxidant-dosing and t2 and t4 refer to the times for purging, are (0.35 s, 10 s, 0.5 s, 12 s). The temperature of the chamber was 100° C. The growth rate of the LT-ALD SnO₂ layer at 105° C. was ˜1.6 Å per cycle. The prepared SnO₂ layer was further thermally annealed at 100° C. for 10 minutes in air. The carbon paste (DD-10, Guangzhou New Seaside Science and Trade Co., Ltd) mixed with PDMS (8 wt. %) and TEGO AddBond (0.5 wt. %, Evonik), was ball-milled overnight before use. Then, carbon paste and cation exchange resin were mixed in with a certain weight ratio and then hand-powdered in an agate mortar. Subsequently, 400 μL of PGMEA was added into the mixture (300 mg) of carbon paste and resins with weight ratios of 10:1, 5:1, 2:1, and further hand-powdered for about 10 minutes. Finally, the mixture was blade coated onto the top of samples with a gap of 50 μm, which was followed by thermal annealing at 100° C. for 10 minutes. For hole-conductor-free carbon perovskite solar cells, SnO₂ (15% in H₂O colloidal dispersion) was first diluted by DI water, and then spin-coated onto ITO glass at a rate of 5,000 rpm and annealed at 170° C. for 30 minutes. MAPbI₃ films were prepared following the same procedure detailed above. For carbon solar modules, SnO₂ and MAPbI₃ were bladed onto ITO substrates, respectively. Subsequently, the mixture of the carbon paste/resins was bladed onto the top of perovskite films and immediately annealed at 100° C. for 10 minutes.

Coating of cation exchange resins. The cation exchange resin particles (<300 μm) were first mixed with a high-concentration NaOH aqueous solution under vigorous stirring to turn the hydrogen form to the sodium form. After being dried in an oven, the sodium form resins were finely powdered in an agate mortar, and then dispersed in solvent by overnight sonic. The surface area and pore diameter were measure by NOVA 2000e. 120 μL of the resin supernate was swiped linearly by a film applicator and then blade-coated onto the surface of perovskite solar cells or modules at a speed of 50 mm s⁻¹. The air knife worked below 20 psi and no thermal annealing was required.

Device characterization. The J-V characteristics of solar cells were obtained using a Xenon-lamp-based solar simulator (Oriel Sol3A, Class AAA Solar Simulator) and the power of the simulated light was calibrated to 100 mW cm⁻² by a silicon (Si) diode (Hamamatsu S1133) equipped with a Schott visible-color glass filter (KG5 color-filter). All cells were measured using a Keithley 2400 source meter with a scan rate of 0.1 V s⁻¹. Carbon-based solar cells were soaked under solar simulator for 10 min before current-voltage sweeping. Scanning electron micrographs (SEM) images were taken on FEI Helios 600 Nanolab Dual Beam System operating at 5 kV. Electron dispersive spectroscopy (EDS) spectrum was obtained with an EDS Oxford instrument (INCA PentaFET-x3).

Device encapsulation. Perovskite solar modules were encapsulated by 1.1-mm-thick glass or 1-mm-thick PP board using a Gorilla epoxy at the bottom sides. The epoxy resin was coated at the edges of glass or the top sides of PP board, and cured for one night before further test. No encapsulation was performed at the top sides of solar modules.

Computation details. A CH₃-terminated styrene monomer worked as a base with −1 charge on sulfonic group. A single Pb²⁺ ion was attached to this. The complete system (monomer+Pb) was thus singly positive. In a sample of 4 independent starting geometries, 3 different possible attachments were found for Pb. The lowest attachment energy of Pb²⁺ to a single monomer was −14.290 eV. The Pb²⁺ ion was then attached to two monomers (“di-monomer”). This was a neutral species. Since the monomers were unconnected, any strain effects in the matrix were not accounted for. This was therefore a best case scenario for Pb adsorption. The resulting attachment energy of Pb²⁺ to the two monomers was −20.200 eV. A single Na⁺ ion was attached to the monomer species for comparison. The combined species was neutral. With 4 independent starting geometries, only one attachment mode was found. The resulting attachment energy of Na⁺ to a single monomer was −5.681 eV. The literature hydration energies of Pb²⁺ and Na⁺ according to Wikipedia/Burgess, J. Metal Ions in Solution (Ellis Horwood, Chichester, 1978) are: −15.338 eV (−1479.9 kJ/mol) and −4.193 eV (−404.6 kJ/mol), respectively. The following is an estimate of exchanging two adsorbed Na+ ions in the polymer matrix with one hydrated Pb²⁺ ion:

2Na⁺(ads,monomer)+Pb²⁺(hyd)->Pb²⁺(ads,di-monomer)+2Na⁺(hyd)

[E_{ads}(Pb²⁺,dimonomer)+2×E_{hyd}(Na⁺)]−[2×E_{ads}(Na⁺)+E_{hyd}(Pb²⁺)]=(−20.200+2×(−4.193))−(2×(−5.681)+(−15.338)) eV=−1.886 eV

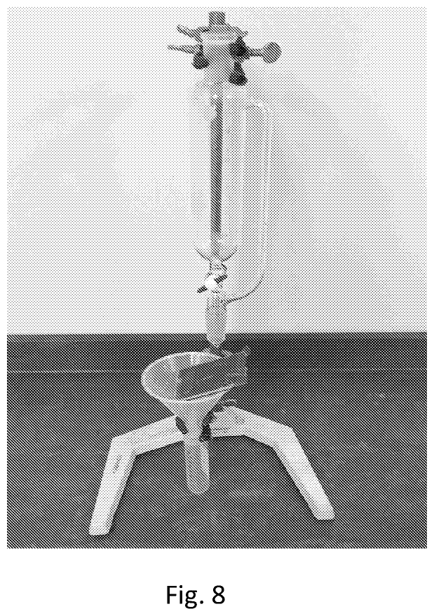

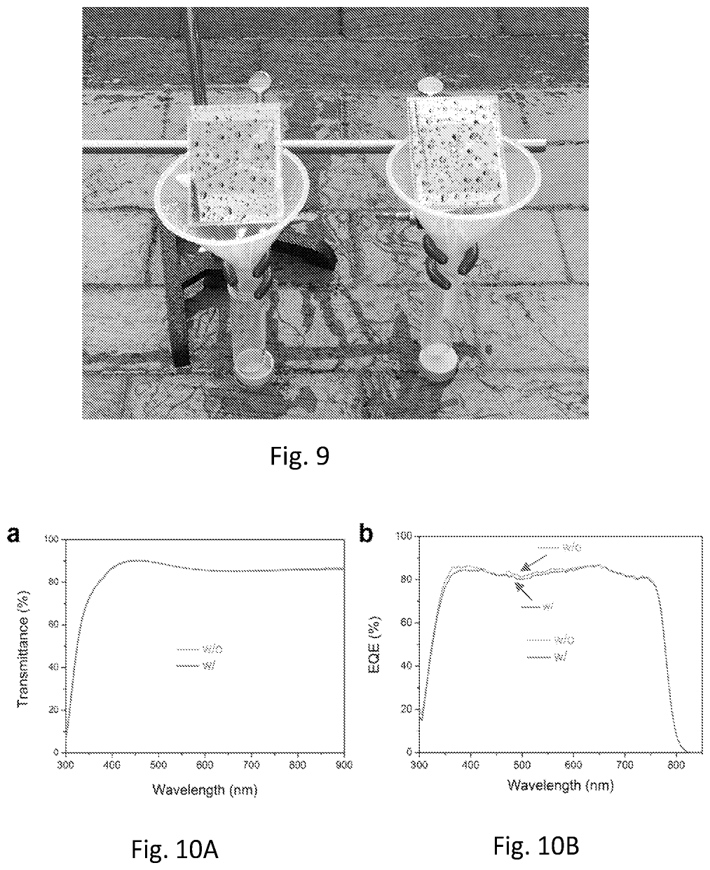

Lead leakage test. All glassware used in lead leakage test was cleaned and rinsed thoroughly with DI water. Perovskite solar cells or modules were first damaged by an ice ball (2-inch diameter) dropped at a certain height. For water-soaking test, perovskite solar cells/modules were immersed into 200 mL DI water, and Pb²⁺ concentration was tested (10 times dilution) every half an hour by ICP-MS Nexion 300D instrument. Before the test, the working curve for analysis was drawn by testing standard solutions prepared by mixing the lead standard solution with 2% HNO₃/DI water solution. For water-soaking test, each damaged solar modules was put in a petri-dish (diameter 15 cm), and 200 mL DI water at different temperature (2, 20, 60 and 85° C.) was slowly poured into the dish from the edge that can completely immerse the whole modules. The lead concentration in contaminated water was detected every half an hour. For the water-dripping test, the damaged perovskite solar modules were mounted on a funnel with an angle of ˜30°. After that, deionized water with a pH of 7 or 4.2 was continuously dripped onto to the device surfaces using a dropping funnel at a rate of 5 mL h⁻¹ for 1 hour (the setup can be found in FIG. 8). The Pb-contaminated water was collected in centrifuge tubes and then further tested by ICP-MS.

### Example 1

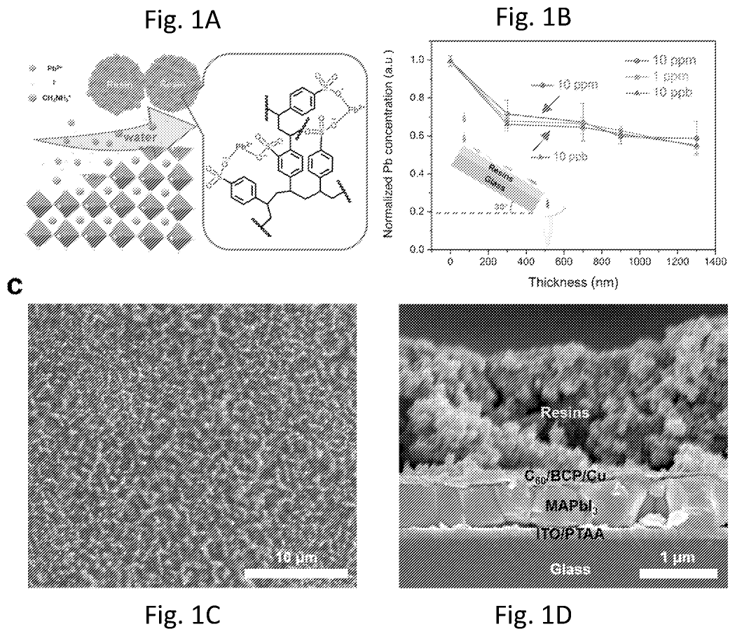

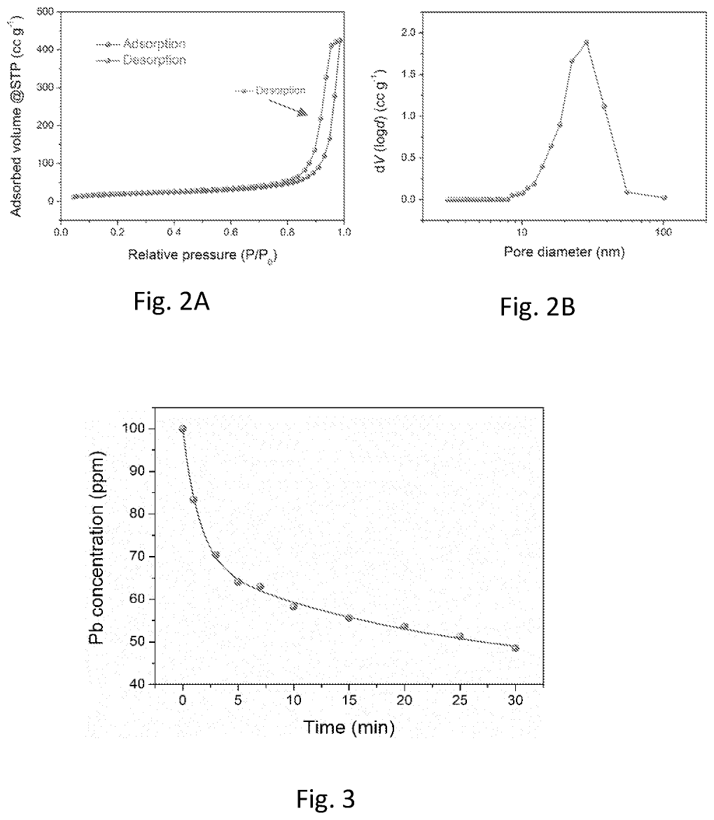

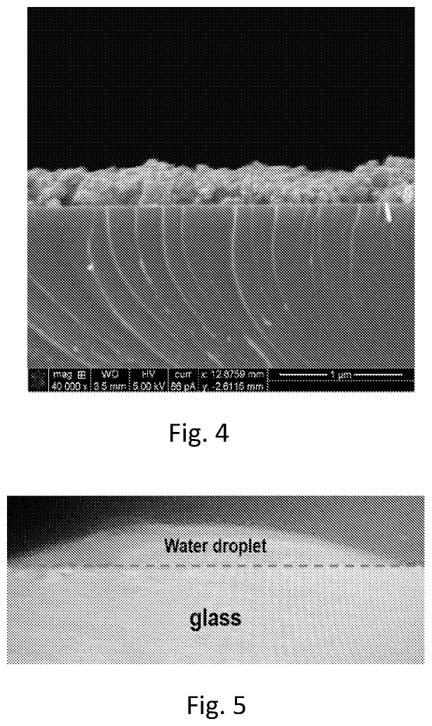

The efficacy of the resin coating layers to prevent lead leakage in perovskite solar modules was examined in the instance where the modules are damaged by severe weather conditions, such as hail (FIG. 1A). The cation exchange resin powder was prepared by grinding strong acid cation exchange resins (sulfonic acid on polystyrene) in an agate mortar. The surface area and pore diameter of the resin powder were measured to be 45.9 m² g⁻¹ and 22.6 nm (FIG. 2A and FIG. 2B) determined by a Brunauer-Emmett-Teller (BET) surface area and pore size analyzer. It is understood that such a high surface area and large pore size can facilitate the adsorption of lead in water. The intrinsic lead-adsorbing properties of the cation exchange resins were then investigated. Here, 10 mg resin powder was added into excess Pb(NO₃)₂ dissolved in deionized (DI) water (50 mL) with an initial lead concentration of 100 ppm, and the in-situ lead concentration was monitored by inductively coupled plasma-mass spectroscopy (ICP-MS). As shown in FIG. 3, the resin powder exhibited fast lead adsorption, and the lead concentration rapidly decreased to 48.5 ppm after 30 min, corresponding to a high lead-adsorption capacity of 257.8 mg g⁻¹ for the resin. In addition, the adsorption rate of lead by a resin layer in flowing water was investigated. Resin-covered glass was prepared by suspending the resin powder in isopropyl alcohol assisted by overnight sonication, and then blade-coating the resin precursor solution onto the top of glass substrates with different thickness from 300 nm to 1300 nm. The resin layer had full coverage on the surface of the glass (FIG. 4). The surface of the resin-covered glass was highly hydrophilic, evidenced by a small water contact angle of ˜13° (FIG. 5). Such good wettability can help water penetrate inside the porous structure of the resins and thus facilitate the absorption of Pb²⁺. In this water-flowing test, each resin-covered glass had a tilt angle of ˜30° with respect to the earth surface. Then, to simulate how fast lead can leak under very heavy rain on solar modules, 1 mL Pb²⁺ aqueous solutions of various concentrations of (10 ppm, 1 ppm, and 10 ppb) were quickly dripped onto the upper end of the glass in less than 1 second, as illustrated in FIG. 1B. The solution was collected at the other end of the glass, and was analyzed by ICP-MS. The flow distance and dwell time of the Pb²⁺ aqueous solution on the glass were 15 cm (the size of the typical perovskite solar mini-modules) and 4 s, respectively. As shown in FIG. 1C, a 300 nm-thick resin layer coated on the glass immediately reduced the lead content in flowing water by 30% in 4 s independent of the initial lead concentration in the solutions. Additionally, the reduction of lead in the water does not change significantly when increasing the thickness of the resin layers. Without wishing to be bound by theory, this suggests that the lead adsorption rate is limited by the diffusion of Pb²⁺ ions from flowing water to the surface of the resins. These results verify the good lead-adsorption properties of cation exchange resins that exhibit both high adsorption capacity and fast adsorption of lead in water.

### Example 2

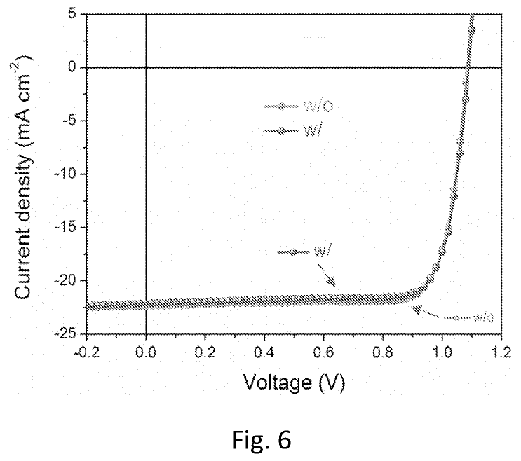

The lead adsorption performance of the cation exchange resins was investigated on perovskite solar devices by blade-coating the resin precursor solution onto the metal electrode of PSCs. The PSCs were fabricated with a p-i-n architecture of indium tin oxide (ITO)/poly(bis(4-phenyl)(2,4,6-trimethylphenyl)amine)(PTAA)/MAPbI₃/C₆₀/bathocuproine (BCP)/copper (Cu). The surface morphology of the pristine resin-covered MAPbI₃ solar cell was first investigated via scanning electron microscopy (SEM) as shown in FIG. 1C and FIG. 1D. The top-view SEM image shows that a compact resin layer was formed on top of the Cu electrode with a full coverage, and the cross-sectional SEM further shows that the resin layer comprises many mesoporous nanoparticles with a size of ˜100 nm. Such mesoporous structures can increase the surface area to adsorb leaked lead. Also investigated was whether such a resin coating layer could have detrimental effects on solar cell efficiencies. The J-V curves of the MAPbI₃ PSC before and after blade-coating cation resins onto copper electrodes are shown in FIG. 6, which indicate that the device had an almost identical PCE after depositing the resin layer. As such, this method allows for the direct coating of a lead-adsorbing resin layer on top of devices without the need to introduce another protection layer, which simplifies the fabrication procedure and thus decreases production cost.

### Example 3

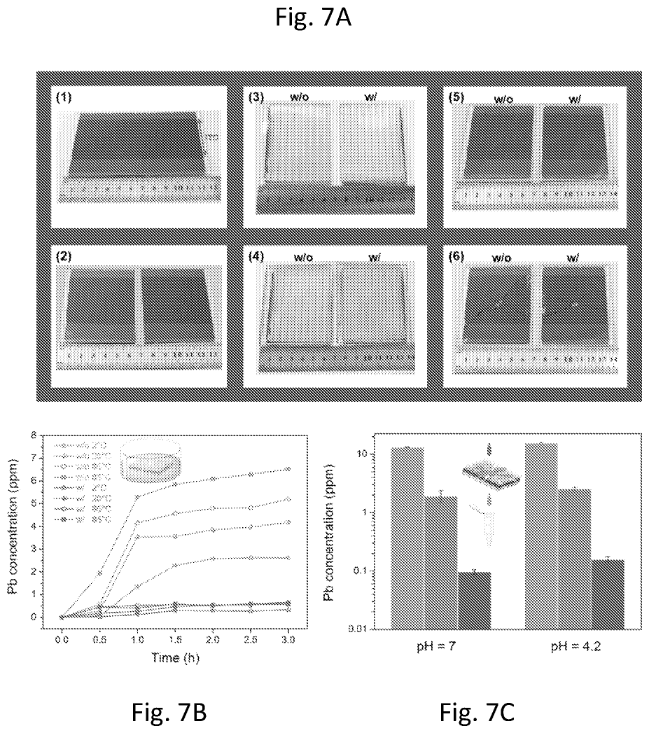

The resin layer was coated onto the top of the metal electrode of perovskite solar mini-modules and then investigated how effectively it could prevent lead leakage in the mini-modules. The MAPbI₃ perovskite solar mini-modules with a structure of ITO/PTAA/MAPbI₃/C₆₀/BCP/metal cathode were fabricated according to a previously reported method (Deng, Y. et al. Sci. Adv. 5, eaax7537, (2019). The area of the MAPbI₃ solar mini-modules (FIG. 7A) used herein was 104.1±2.3 cm². To exclude the impact of module-to-module variation on the lead leakage study, the perovskite solar modules of investigation were cut into two almost identical small mini-modules, one of which worked as a control and the other which was coated with cation exchange resins. Both mini-modules were then encapsulated by 1.1-mm-thick glass using epoxy coated at the edges of the mini-modules. After that, both mini-modules were broken by dropping an ice ball at a fixed height to simulate hail damage to perovskite modules in realistic operation conditions, following the ASTM E1038 standard of testing photovoltaic panels for hail impact resistance (Determining resistance of photovoltaic modules to hail by impact with propelled ice balls, astm e1038-10.). After the impact damage by ice, star-shaped cracks appeared at the impact positions, and both the ITO substrate and encapsulation glass were broken. The damaged area and the size of the cracks of the two mini-modules were very similar in each test.

### Example 4

The lead leakage of the damaged solar mini-modules was first tested by water-soaking to simulate the worst-case scenario when damaged modules are flushed by rain or flood. In this test, each damaged sub-module was put in a petri-dish (diameter 15 cm), and 200 mL of DI water of different temperatures (2, 20, 60 and 85° C.) was poured into the petri-dish to fully soak the whole sub-modules. The lead concentration in the contaminated water was then measured by ICP-MS every half an hour. The results are shown in FIG. 7B. At temperatures below 60° C., the concentration of lead leaking out of both modules was relatively low in the first half hour. Without wishing to be bound by theory, it is understood that this could be caused by the slow permeation of water into the perovskite layer during this stage. After an hour, the lead concentration from the modules without the resin coating increased dramatically, suggesting that the electrode and the charge transport layer were no longer able to prevent water permeation. In addition, the lead leakage rate increased with temperature for the modules without the resin layer. In striking contrast, the damaged solar modules with the resin coatings exhibited very small lead leakage regardless of temperature, and their lead concentration eventually reached a plateau after two hours, when the control modules still continued leaking lead. At the end of the tests, the lead sequestration efficiencies were 86%, 87%, 87% and 90% at 2, 20, 60 and 85° C., respectively. These values were calculated by the concentration ratio of lead leaking out of the damaged modules with and without resin layers. These results clearly verify that the resin layers can effectively prevent lead leakage in damaged perovskite modules.

### Example 5

Water was then dripped on damaged solar modules without and with resin layers to simulate heavy rainfall right after the impact of hail. At least three mini-modules were tested in each lead leakage measurement. Each damaged solar mini-module was put in a funnel with a tilt angle of ˜300 with respect to the earth's surface. DI water (pH=7) was dripped at a rate of 5 mL h⁻¹ for 1 hour. The spread area of water on the glass was ˜1 cm² to cover the damaged area, corresponding to a heavy rainfall of 5 mm h⁻¹. Contaminated water passing through the damaged solar modules was collected in a centrifuge tube and then detected by ICP-MS (the measurement setup can be found in FIG. 8). After 1-hour of water dripping, a yellow color product was observed around the star-shaped cracks in both types of mini-modules. The averaged lead concentration in the contaminated water from testing of the three mini-modules without a resin layer was 13.24±0.25 ppm. This value was significantly reduced to 1.92±0.46 ppm from testing of the perovskite mini-modules with resin layers. (FIG. 7B). To further simulate a heavy acidic rainfall right after the hail impact, acidic water (pH=4.2) was also dripped onto damaged solar mini-modules. Similarly, the resin coating layer reduced the averaged lead concentration from 15.50±0.50 ppm to 2.55±0.14 ppm, and a comparable lead sequestration efficiency of 84% was obtained.

A 1-hour outdoor lead leakage test was conducted on a rainy day in North Carolina as shown by the photos in Extended Data FIG. 7. The rainfall was 1.6 mm with a pH of ˜6, and water passing through damaged solar mini-modules was collected following the same procedure. The ICP-MS analysis indicates that the resin coating layer reduced the lead concentration in the collected water from 3.68±0.07 to 0.32±0.04 ppm, corresponding to a high lead sequestration efficiency of 91%. These results clearly verify that the resin layers can effectively reduce lead leakage when perovskite solar modules are damaged.

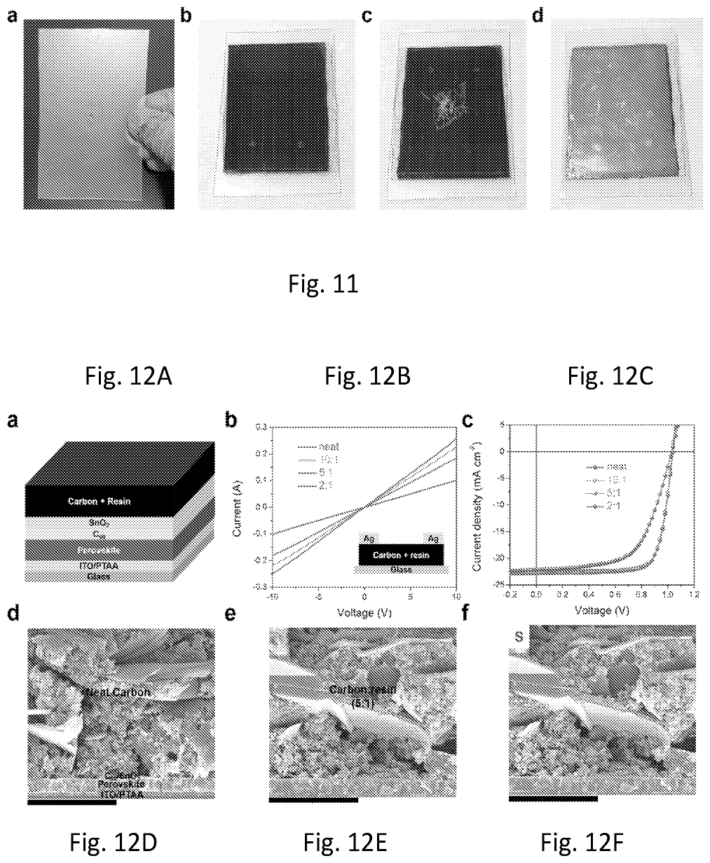

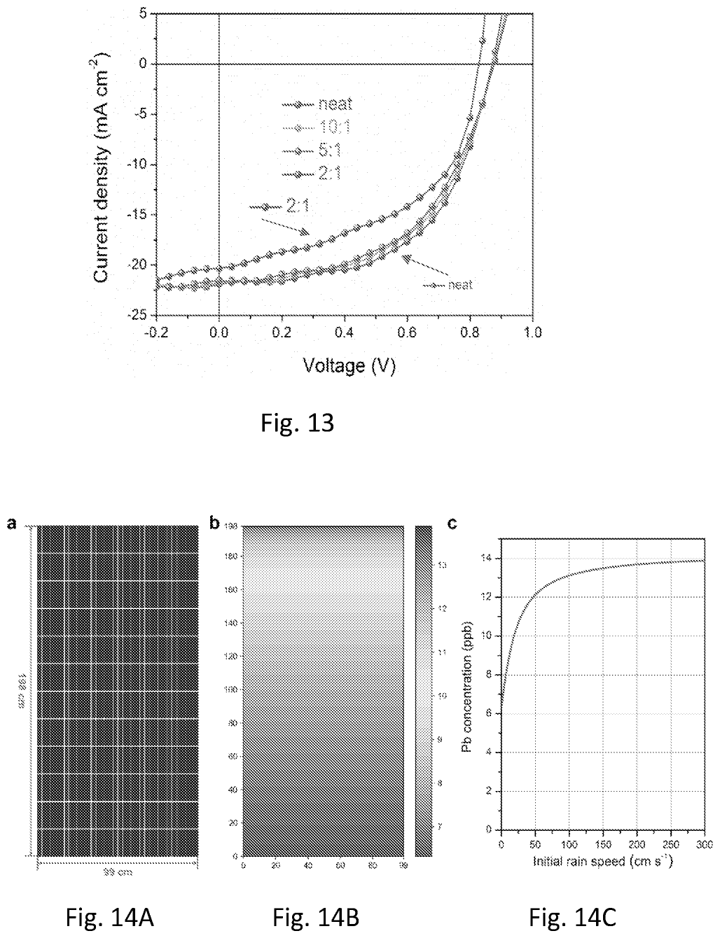

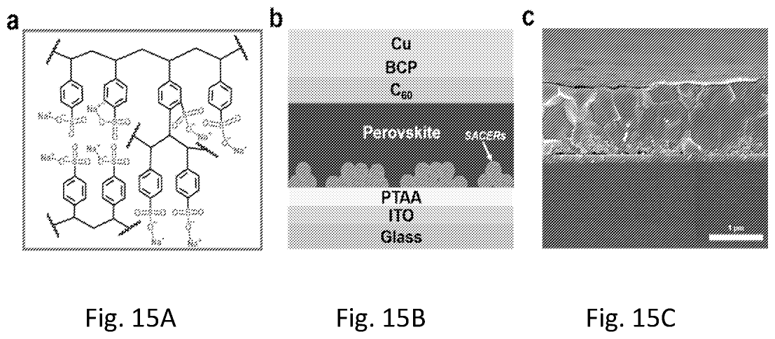

During the water-dripping experiments, water penetrated the damaged modules through cracks and then dissolved perovskite materials. In this case, most of the dissolved lead will be captured by the resin layer coated on the electrode, but a small portion of the lead can still leak out from the glass surface of the damaged modules. To further block this lead leakage pathway, one or more resin layers was blade-coated on the front surface of the solar modules (on glass) to further adsorb leaked lead. A 300 nm thick resin layer was found to have no noticeable effect on the transmittance of the ITO glass substrates and external quantum efficiency spectrum of the MAPbI₃ solar cells, as shown in FIG. 10A and FIG. 10B. A 1-mm-thick polypropylene (PP) board was also used to encapsulate the metal electrodes of the modules, as a polymer frame is often used in solar modules (FIG. 11). The same neutral and acidic water dripping tests were conducted and it was discovered that the lead leakage rates were further reduced. A high lead sequestration efficiency of 99% was realized in both tests with residual lead concentrations of 96.5±8.4 ppb in DI water and 157±17 ppb in acidic water. This result suggests that a thin resin on glass substrates together with an encapsulation material can further reduce lead leakage.

### Example 6

Lead leakage was further reduced by incorporating the cation exchange resins into carbon-based electrodes. Carbon materials have shown great success as electrodes for perovskites due to their low cost, solution processability, and good stability with perovskites, while many known metals used in solar cells react with perovskites (Fagiolari, L. & Bella, F. Energy Environ. Sci. 12, 3437-3472, (2019); Meng, F. N. et al. J. Mater. Chem. A 7, 8690-8699, (2019); Mei, A. et al. Science 345, 295-298, (2014)). Carbon electrodes made from carbon paste contain both graphite and carbon black with loose connections due to the size mismatch between graphite flakes and carbon black clusters. The loose structure can accommodate small-sized resin nanoparticles without sacrificing the conductivity of the carbon electrodes. To test this, carbon paste and cation resins were mixed with various weight ratios of 10:1, 5:1, 2:1, and the conductance of all four carbon films was tested with a lateral structure of glass/carbon film/Ag. As shown in FIG. 12A, the I-V curves in the dark show that the conductance decreases with increased loading of the resins, but the carbon films with 10% and 20% resin still maintain good conductance while 50% resin significantly decreases the conductance of the carbon electrodes. The solar cells were subsequently fabricated with a structure of ITO/PTAA/Rb_{0.05}Cs_{0.05}FA_{0.85}MA_{0.05}PbI_{2.85}Br_{0.15}/C₆₀/atomic layer deposited SnO₂/carbon electrode. The PSCs based on the carbon paste with 10% and 20% of resin maintained PCEs of 18.0% and 17.9%, respectively, which are comparable to that of the device with neat carbon paste (18.1%) (Table 1).

TABLE 1
Device parameters of carbon-based solar
cells with different carbon electrodes

| Ratio of carbon paste | | | | |
|---|---|---|---|---|
| and resin | V_{oc} (V) | J_{sc} (mA cm⁻²) | FF | PCE (%) |
| Neat carbon paste | 1.04 | 22.6 | 0.769 | 18.1 |
| 10:1 | 1.03 | 22.8 | 0.766 | 18.0 |
| 5:1 | 1.04 | 22.8 | 0.756 | 17.9 |
| 2:1 | 1.03 | 22.2 | 0.603 | 13.8 |

(V_{oc}, open-circuit voltage; J_{sc}, short-circuit current density; FF, fill factor.)

These results agree with the unchanged morphology of the carbon paste after addition of 20% resin, as shown by the cross-sectional SEM images in FIG. 12D-12E, which also indicate that addition of the resin by 20% does not deteriorate the contact of the carbon paste with the underlying perovskite/C₆₀/SnO₂ films. Electron dispersive spectroscopy (EDS) mapping in FIG. 12F shows that the sulfur was uniformly distributed on all the carbon clusters. The carbon-resin mixture electrode was also tested in a hole-conductor-free solar cell with a structure of ITO/SnO₂/MAPbI₃/carbon electrode, and a

TABLE 2
Device parameters of hole-conductor-free PSCs
with different carbon electrode compositions

| Ratio of carbon paste | | | | |
|---|---|---|---|---|
| and resin | V_{oc} (V) | J_{sc} (mA cm⁻²) | FF | PCE (%) |
| Neat carbon paste | 0.87 | 21.9 | 0.563 | 10.7 |
| 10:1 | 0.88 | 21.7 | 0.542 | 10.4 |
| 5:1 | 0.88 | 21.6 | 0.534 | 10.2 |
| 2:1 | 0.83 | 20.3 | 0.506 | 8.5 |

(V_{oc}, open-circuit voltage; J_{sc}, short-circuit current density; FF, fill factor.)

The same lead leakage test was conducted to investigate how effectively the carbon:resin electrode with a weight ratio of 5:1 can reduce lead leakage in damaged hole-conductor-free structure solar mini-modules. The acidic water dripping test shows that the application of resins on both the carbon electrode and the glass surface effectively reduced lead leakage by 98% from 891±39 to 14.3±1.5 ppb. For reference, the residual lead concentration safe level is 15 ppb for drinking water, according to U.S. Federal 40 CFR 141 regulation.

Lead leakage was studied in large area solar panels based on the measured results. In a large-area solar panel, water can flow through the whole panel and thus lead can be further adsorbed by the resin coated on the glass. The lead leakage was simulated in a carbon-based perovskite solar panel with a typical size of 198 cm×99 cm mounted at a tilt angle of ˜30° with respect to the earth's surface. The panel featured 72 mini-modules as illustrated in FIG. 14A. The simulation to evaluate lead leakage was undertaken in the worst scenario, i.e. under heavy and acidic rainfall (5 mm h⁻¹, pH 4.2), wherein each cell was damaged. It was assumed that the rainwater was well spread and that a lead concentration of 14.3 ppb leaked into the rainwater once it fell on the damaged panel, which would then be further purified when it flowed onto the resin-covered solar panel. For each location of the solar panel, the lead leaking out of the underlying damaged perovskites and flowing from the upper locations under heavy rain flow were considered. By calculating the lead adsorption rate between rainwater and resins, the lead concentration in the rainwater was obtained at each location and its distribution was mapped on the whole solar panel synchronously. First, the initial speed of the rainwater was set to zero when it fell on the solar panel and it further speeded up due to gravitational acceleration. During this process, the lead adsorption between rainwater and front resins is regarded a diffusion-controlled process as shown in FIG. 1B and thus the Lagergren equation can be used to describe this process: C₀−Cₜ=C₀(1−e^{-kt}), wherein k is the adsorption constant and can be determined by water flowing test results, t is flowing time on the surface of the solar panel, C₀ is the initial lead concentration in the rain, and Cₜ is the concentration after the rain reaches the bottom of solar panel (S., L. Sven. Vetenskapsakad. Handingarl 24, 1-39, (1898). Both the speed acceleration and adsorption constants can be determined by the water-flowing results in FIG. 1B. As a result, the lead concentration distribution was mapped on the carbon solar panel as show in FIG. 14B, and the resin coating layer on the solar panel further purified the lead-containing rain gradually. The lead concentration in the rainwater reaching the bottom of the solar panel was simulated to 6.33 ppb, which was effectively reduced compared with the initial lead concentration and even approached the safe level of bottle drinking water (5 ppb) in the USA. These results simulated under the worst-case scenario further verify the efficacy of low-cost resin coatings in preventing lead leakage in damaged perovskite solar panels. In this simulation, a figure-of-merit is the initial rain flow speed, which determines the dwell time of lead-containing rain on the solar panel. Here, the final lead concentration of rain versus the rain initial flow speed was simulated as shown in FIG. 14C. Slower flow speed resulted in better lead sequestration effects, because it provided sufficient time for lead adsorption between the rainwater and the resins.

### Example 7

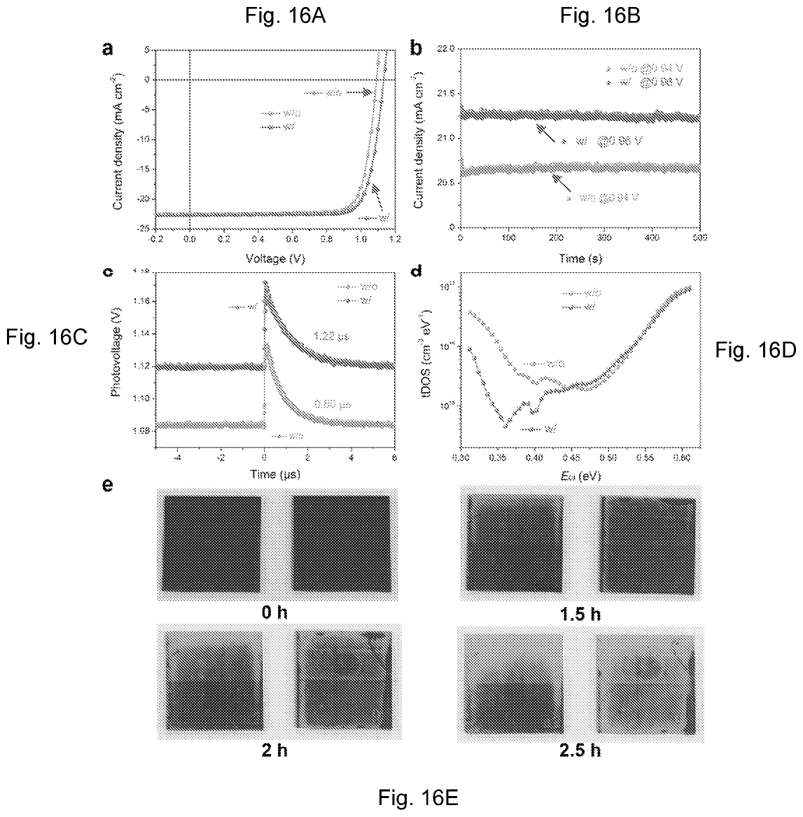

In another series of experiments, the resins were incorporated into the perovskite layer of solar cells. FIG. 16A shows the photocurrent-voltage characteristics of the MAPbI₃ solar cells with and without embedded SACERs. The control device delivered a Vo, of 1.09 V, a J_{sc} of 22.7 mA cm⁻², a FF of 0.801, and a PCE of 19.8%. However, after the SACERs were incorporated into the perovskite layer, the PCE of the resulting solar cell was improved to 20.6% with a V_{oc} of 1.13 V, a J_{sc} of 22.6 mA cm⁻², and FF of 0.806. The stabilized power outputs were 20.6% and 19.5% for the solar cells with and without SACERs, respectively (FIG. 16B). The enhanced Vo, can be attributed to suppressed non-radiative recombination, which is supported by the longer charge recombination lifetime measured by transient photovoltage (TPV) at a light bias of 1 sun intensity (FIG. 16C). A reduced trap density in the SACER-integrated solar cell was also discovered by thermal admittance spectroscopy measurements shown in FIG. 16D. Without wishing to be bound by theory, it this could be a result of Na⁺ in the SACERs, which can passivate the shallow traps in perovskite solar cells (Bi, C. et al, J. ACS Energy Lett. 2, 1400-1406, (2017). Furthermore, the light-soaking test on the MAPbI₃ films showed that the incorporation of the SACERs layer has no detrimental effects on the photostability of the perovskite light absorbers.

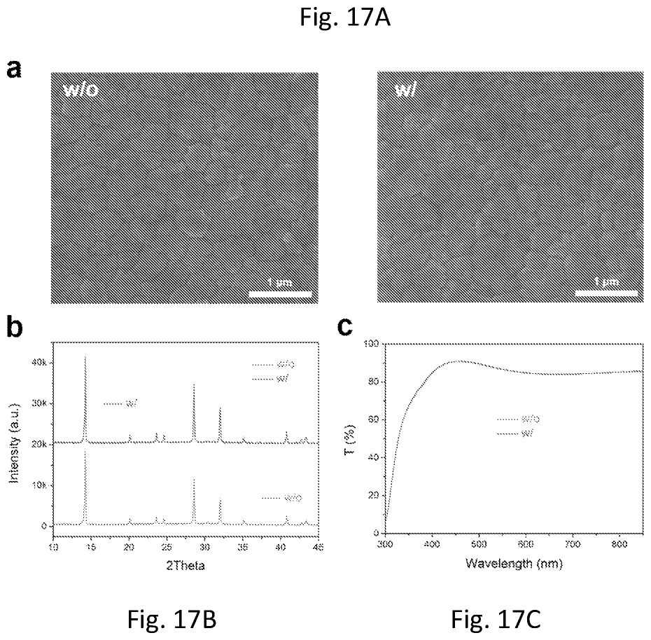

The potential effects of the embedded SACERs on the morphology of MAPbI₃ and on the transmittance of the ITO glass substrates were further investigated (FIG. 17A). The top-view SEM images and XRD spectra show no noticeable change in the surface morphology or film crystallinity after integrating SACERs beneath the perovskite layer. In addition, the transmittance of the identical ITO glass substrate remained nearly the same after applying the SACER coating layer, as shown in FIG. 17C.

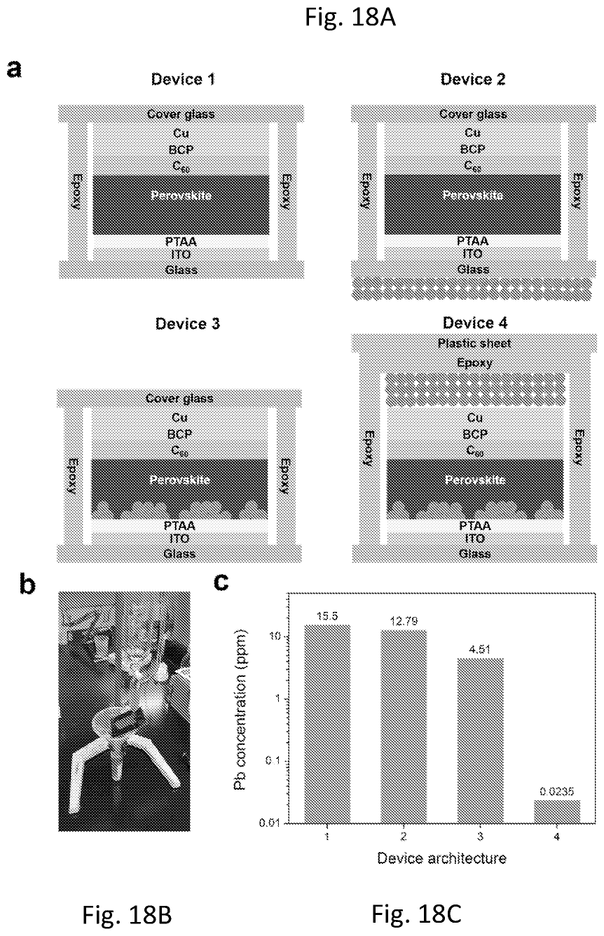

Subsequently, perovskite mini-modules (8 cm×6.5 cm) with different device architectures were fabricated (FIG. 18A) and the amount of lead that they leaked was tested with ICP-MS after being damaged and dripped with 5 mL of acidic water (pH=4.2) in 1 hour. The setup of the water-dripping test is shown in FIG. 18B. Device 1 without employing any lead adsorbent showed a higher amount of leaked lead (15.5 ppm) in acidic water. The incorporation of SACERs onto the glass surface (Device 2) or the perovskite layer (Device 3) reduced the amount of leaked lead. However, the embedded SACERs in the perovskite layer proved to be more effective in preventing lead leakage than that on the surface of the glass substrate by reducing lead leakage from 12.79 ppm to 4.51 ppm. To further reduce the lead leakage, a thick SACER layer (1.8 μm) was blade-coated on top of the copper electrode and the cover glass was replaced with a plastic sheet for better encapsulation. The resulting Device 4 exhibited a much lower lead leakage amount of 23.5 ppb, approaching the U.S. Federal 40 CFR 141 regulation's safe lead level in drinking water (15 ppb).

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Throughout this specification and the claims, the words “comprise,” “comprises,” and “comprising” are used in a non-exclusive sense, except where the context requires otherwise. It is understood that embodiments described herein include “consisting of” and/or “consisting essentially of” embodiments.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other embodiments set forth herein will come to mind to one skilled in the art to which this subject matter pertains having the benefit of the teachings presented in the foregoing descriptions and the associated drawings. Therefore, it is to be understood that the subject matter is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A solar cell, comprising:
an active layer comprising a perovskite composition, wherein said perovskite composition comprises lead; and
a lead absorbing material, wherein said lead absorbing material does not comprise:
P,P′-di(2-ethylhexyl)methanediphosphonic acid;
enediaminetetrakis(methylenephosphonic acid); or
tetraethylene glycol-substituted 2,1,3-benzothiadiazole.

2. The solar cell of claim 1, wherein said lead absorbing material is an ion exchange material.

3. The solar cell of claim 2, wherein said ion exchange material comprises a negatively-charged functional group selected from the group consisting of SO₃²⁻ (sulfite), SO₃⁻ (sulfonate), SO₄²⁻ (sulfate), C₆H₅O₇⁻³ (citrate), C₄H₄O₆²⁻ (tartrate), PO₄³⁻ (phosphate), CO₃²⁻ (carbonate), AsO₄³⁻ (arsenate), ClO₄⁻ (perchlorate), SCN⁻ (thiocyanate), S₂O₃²⁻ (thiosulfate), WO₄²⁻ (tungstate), MoO₄²⁻ (molybdate), CrO₄²⁻ (chromate), C₂O₄²⁻ (oxalate), HSO₄⁻ (hydrogen sulfate), HPO₄²⁻ (hydrogenphosphate), NO₃⁻ (nitrate), NO₂⁻ (nitrite), CN⁻ (cyanide), Cl⁻ (chloride), HCO₃⁻ (bicarbonate), H₂PO₄⁻ (dihydrogenphosphate), CH₃COO⁻ (acetate), IO₃⁻ (iodate), HCOO⁻ (formate), BrO₃⁻ (bromate), CO₃⁻ (chlorate), F⁻ (fluoride), and OH⁻ (hydroxide).

4. The solar cell of claim 3, wherein said ion exchange material comprises a sulfonate functional group.

5. The solar cell of claim 4, wherein said ion exchange material is a polystyrene sulphonate.

6. The solar cell of claim 5, wherein said polystyrene sulphonate is a crosslinked polystyrene sulphonate.

7. The solar cell of claim 6, wherein said crosslinked polystyrene sulphonate is selected from the group consisting of crosslinked calcium polystyrene sulphonate, crosslinked hydrogen polystyrene sulphonate, crosslinked sodium polystyrene sulphonate, and crosslinked potassium polystyrene sulphonate.

8. The solar cell of claim 7, wherein said crosslinked polystyrene sulphonate is crosslinked sodium polystyrene sulphonate.

9. The solar cell of claim 1, wherein said lead absorbing material is a neutral molecule that can form a complex with lead.

10. The solar cell of claim 9, wherein said neutral molecule is selected from the group consisting of crown ether, cyclodextrin, porphyrin, calixarene, calixcarbazole, pillararene, and cucurbituril.

11. The solar cell of claim 1, wherein said perovskite composition has a formula of ABX₃,
where A is a cation selected from the group consisting of methylammonium (MA), tetramethylammonium, formamidinium (FA), cesium, rubidium, potassium, sodium, calcium, butylammonium, phenethylammonium, phenylammonium, guanidinium, ammonium, and a combination thereof;
B is a metal cation comprising lead; and
X is selected from the group consisting of chloride, bromide, fluoride, iodide, thiocyanate, and a combination thereof.

12. The solar cell of claim 11, wherein said perovskite composition is selected from the group consisting of MAPbI₃, MAPbBr₃, and MAPbCl₃.

13. The solar cell of claim 11, wherein A is selected from the group consisting of Cs, FA, MA, Rb, and a combination thereof; B is lead; and X is selected from the group consisting of iodide, bromide, and a combination thereof.

14. The solar cell of claim 13, wherein said perovskite composition is RbₓCs_{y}FA_{1-x-y-z}MA_{z}PbI_{3-f}Br_{f}((x+y+z)<1; f<3).

15. The solar cell of claim 14, wherein said perovskite composition is Rb_{0.05}Cs_{0.05}FA_{0.85}MA_{0.05}PbI_{2.85}Br_{0.15}.

16. The solar cell of claim 1, further comprising:
a transparent conductive oxide layer and a metal electrode;
wherein:
said perovskite composition is disposed on said transparent conductive oxide layer and said metal electrode is disposed on said perovskite composition.

17. The solar cell of claim 1, further comprising:
a first transparent conductive oxide layer and a second transparent conductive oxide layer;
wherein:
said perovskite composition is disposed on said first transparent conductive oxide layer and said second transparent conductive oxide layer is disposed on said perovskite composition.

18. The solar cell of claim 17, wherein said lead absorbing material is in a lead absorbing material layer, wherein said lead absorbing material layer is disposed on said second transparent conductive oxide layer or said first transparent conductive oxide layer is disposed on said lead absorbing material layer.

19. The solar cell of claim 16, further comprising:
a first transport layer and a second transport layer;
wherein:
said first transport layer is disposed directly on said transparent conductive oxide layer;
said perovskite composition is disposed on said first transport layer;
said second transport layer is disposed on said perovskite composition; and
said metal electrode is disposed on said second transport layer.

20. The solar cell of claim 19, further comprising a glass layer, wherein said transparent conductive oxide layer is disposed directly on said glass layer.

21. The solar cell of claim 20, wherein said lead absorbing material is in a lead absorbing material layer, wherein said glass layer is disposed directly on said lead absorbing material layer.

22. The solar cell of claim 20, wherein said lead absorbing material is in a lead absorbing material layer, wherein said lead absorbing material layer is disposed directly on said first transport layer, and said perovskite composition is disposed directly on said lead absorbing material layer.

23. The solar cell of claim 20, wherein said lead absorbing material is admixed with said perovskite composition.

24. The solar cell of claim 20, wherein said lead absorbing material is in a lead absorbing material layer, wherein said lead absorbing material layer is disposed directly on said metal electrode.

25. The solar cell of claim 20, wherein said lead absorbing material is in a first lead absorbing material layer and a second lead absorbing material layer;
wherein said glass layer is disposed directly on said first lead absorbing material layer, and
said second lead absorbing material layer is disposed directly on said metal electrode.

26. The solar cell of claim 20, wherein said lead absorbing material is in a first lead absorbing material layer and a second lead absorbing material layer;
wherein said glass layer is disposed directly on said first lead absorbing material layer; and
said second lead absorbing material layer is disposed directly on said first transport layer, wherein said perovskite composition is disposed directly on said second lead absorbing material layer.

27. The solar cell of claim 20, wherein said lead absorbing material is in a first lead absorbing material layer and a second lead absorbing material layer;
wherein said first lead absorbing material layer is disposed directly on said first transport layer, wherein said perovskite composition is disposed directly on said first lead absorbing material layer; and
said second lead absorbing material layer is disposed directly on said metal electrode.

28. The solar cell of claim 20, wherein said lead absorbing material is in a first lead absorbing material layer and a second lead absorbing material layer;
wherein said first lead absorbing material layer is disposed directly on said first transport layer, wherein said perovskite composition is disposed directly on said first lead absorbing material layer, and;
said second lead absorbing material layer is disposed directly on said perovskite composition, wherein said second transport layer is disposed directly on said second lead absorbing material layer.

29. The solar cell of claim 20, wherein said lead absorbing material is in a lead absorbing material layer, wherein:
said lead absorbing material layer is disposed directly on said perovskite composition, wherein said second transport layer is disposed directly on said lead absorbing material layer.

30. The solar cell of claim 20, wherein said lead absorbing material is in a first lead absorbing material layer, a second lead absorbing material layer, and a third lead absorbing material layer, wherein:
said glass layer is disposed directly on said first lead absorbing material layer;
said second lead absorbing material layer is disposed directly on said first transport layer, wherein said perovskite composition is disposed directly on said second lead absorbing material layer; and
said third lead absorbing material layer is disposed directly on said metal electrode.

31. The solar cell of claim 24, wherein said transparent conductive oxide layer is ITO, said first transport layer is PTAA, said perovskite composition is MAPbI₃, said second transport layer comprises C60; said solar cell further comprises a buffer layer comprising BCP, wherein said first layer of C60 is disposed directly on said perovskite composition and said buffer layer comprising BCP is disposed directly on said layer of C60; said metal electrode is copper, wherein said metal electrode is disposed directly on said layer of BCP; and said lead absorbing material is crosslinked sodium polystyrene sulphonate, wherein said lead absorbing material is disposed directly on said metal electrode.

32. A solar module, comprising a plurality of the solar cell of claim 31.

33. The solar cell of claim 25, wherein said first lead absorbing material layer is crosslinked sodium polystyrene sulphonate; said first transport layer is PTAA; said perovskite composition is MAPbI₃; said second transport layer comprises C60; said solar cell further comprises a buffer layer comprising BCP, wherein said first layer of C60 is disposed directly on said perovskite composition and said buffer layer comprising BCP is disposed directly on said layer of C60; said metal electrode is copper, wherein said metal electrode is disposed directly on said layer of BCP; and said second lead absorbing material layer is crosslinked sodium polystyrene sulphonate, wherein said second lead absorbing material is disposed directly on said metal electrode.

34. A solar module, comprising a plurality of the solar cell of claim 33.

35. The solar cell of claim 1, further comprising a carbon electrode.

36. The solar cell of claim 35, wherein said carbon electrode comprises a carbon paste comprising graphite and carbon black.

37. The solar cell of claim 35, wherein said lead absorbing material is admixed with said carbon electrode.

38. The solar cell of claim 37, wherein said lead absorbing material is admixed with said carbon electrode in a ratio from 1:10000 to 10:1.

39. The solar cell of claim 37, wherein said lead absorbing material is admixed with said carbon electrode in a 1:5 ratio.

40. The solar cell of claim 37, further comprising:
a transparent conductive oxide layer;
wherein said perovskite composition is disposed on said transparent conductive oxide layer; and
said carbon electrode is disposed on said perovskite composition.

41. The solar cell of claim 40, further comprising:
a first transport layer;
wherein said first transport layer is disposed on said transparent conductive oxide layer;
said perovskite composition is disposed on said first transport layer; and
said carbon electrode is disposed on said perovskite composition.

42. The solar cell of claim 41, further comprising a glass layer, wherein said transparent conductive oxide layer is disposed directly on said glass layer.

43. The solar cell of claim 42, wherein said lead absorbing material further comprises a lead absorbing material layer, wherein said glass layer is disposed directly on said lead absorbing material layer.

44. The solar cell of claim 41, wherein said first transport layer is an electron transport layer.

45. A solar module, comprising a plurality of the solar cell of claim 41.

46. The solar cell of claim 41, further comprising a second transport layer, wherein said second transport layer is disposed on said perovskite composition and said carbon electrode is disposed on said second transport layer.

47. The solar cell of claim 46, wherein said transparent conductive oxide layer is ITO; said first transport layer is PTAA; said perovskite composition is Rb_{0.05}Cs_{0.05}FA_{0.85}MA_{0.05}PbI_{2.85}Br_{0.15}; and said second transport layer comprises C₆₀ and SnO₂.

48. The solar cell of claim 16, further comprising a first glass layer and a second glass layer, wherein said conductive oxide layer is disposed on said first glass layer and said second glass layer is disposed on said conductive electrode.

49. The solar cell of claim 48, wherein said glass layer is about 1.1 mm.

50. The solar cell of claim 16, wherein said metal electrode has a thickness of about 1 nm to about 1000 μm.

51. The solar cell of claim 16, wherein said transparent conductive oxide layer has a thickness of about 1 nm to about 1000 μm.

52. The solar cell of claim 19, wherein said first transport layer and said second transport layer each have a thickness of about 0.1 nm to about 10 μm.

53. The solar cell of claim 1, wherein when said lead absorbing material is in a lead absorbing layer, said layer has a thickness of about 0.1 nm to about 1000 μm.

54. The solar cell of claim 1, wherein said solar cell is a single junction solar cell.

55. The solar cell of claim 1, wherein said solar cell is a tandem solar cell.

56. The solar module of claim 45, further comprising a polymer encapsulation.

57. The solar module of claim 56, wherein said polymer encapsulation is affixed to the backside of said solar module.

58. The solar module of claim 56, wherein said polymer encapsulation comprises polypropylene.
